(19) United States
(12) Patent Application Publication
(10) Pub. No.: US 2009/0250594 A1
(43) Pub. Date: Oct. 8, 2009

(54) SOLID-STATE IMAGE SENSOR AND MANUFACTURING METHOD THEREOF

(75) Inventors: Keisuke Tanaka, Osaka (JP); Yutaka Hirose, Kyoto (JP); Toshinobu Matsuno, Kyoto (JP); Kimiaki Toshikiyo, Osaka (JP); Motonori Ishii, Osaka (JP)

Correspondence Address: GREENBLUM & BERNSTEIN, P.L.C., 1950 ROLAND CLARKE PLACE, RESTON, VA, 20191, US

(73) Assignee: Panasonic Corporation, Osaka (JP)

(21) Appl. No.: 12/415,127

(22) Filed: Mar. 31, 2009

(30) Foreign Application Priority Data
Apr. 4, 2008 (JP) 2008-098643

(51) Int. Cl. H01L 27/146; H01L 21/00; H01L 27/14

(52) U.S. Cl. 250/208.1; 438/70; 257/E21.001; 250/338.4

(57) ABSTRACT

A solid-state image sensor that has a high pixel count and includes a color filter having high color reproducibility is provided. The solid-state image sensor includes: light-collecting elements each of which is a medium containing dispersant particles; light-receiving elements each of which is provided for a corresponding one of the light-collecting elements, and which receives light collected by the corresponding one of the light-collecting elements and generates an electric signal; and electrical wiring for transferring the electric signal, wherein each of the light-collecting elements has one of plural light-dispersion functions that are different depending on the corresponding light-receiving elements.

### BACKGROUND OF THE INVENTION

(1) Field of the Invention

The present invention relates to a solid-state image sensor used in a digital camera and the like, and particularly to a solid-state image sensor having minute pixels necessary for realizing a high pixel count or a small chip area.

(2) Description of the Related Art

With the widespread use of digital cameras and camera-equipped mobile phones, the market for solid-state image sensors has expanded significantly. In addition, there has been a stronger demand for thinner digital still cameras in recent years. Stated differently, this means that the lens used in the camera portion has a short focus, and light incident on the solid-state image sensor becomes wide angled (a large angle when measured from the vertical axis of the incidence plane of the solid-state image sensor). Furthermore, single-lens reflex digital cameras which allow interchanging use of various lenses, from wide-angle to telescopic, are becoming popular.

In solid-state image sensors such as a CCD or MOS image sensor, a semiconductor integrated circuit including light-receiving portions is laid out two-dimensionally, and light signals from a subject are converted to electric signals. Since the sensitivity of the solid-state image sensor is defined by the size of the output current of a light-receiving element with respect to the amount of incident light, reliable introduction of incident light to the light-collecting elements is an important component for improvement of sensitivity.

FIG. 22 is a diagram showing an example of the basic structure of a typical conventional pixel. As shown in FIG. 22, light 53 (light indicated by a broken line) perpendicularly incident on a microlens 57 is color-separated by any of a red (R), green (G), or blue (B) color filter 2 then converted to an electric signal in a light-receiving element 6, and transmitted by an electric signal transmission unit 4. Since a relatively high light-collection efficiency can be obtained, the microlens 57 is used in almost all solid-state image sensors.

However, with the microlens 57 as that described above, light-collection efficiency decreases dependently on the incidence angle of signal light. Specifically, although light-collection for light 53 perpendicularly incident on the lens can be carried out efficiently, light-collecting efficiency decreases with respect to oblique incident light 56. This is because the oblique incident light 56 is blocked by electrical wiring 3 in the pixel and cannot reach the light-receiving element 6.

Since improvement of picture quality of solid-state imaging devices is constantly demanded, increasing pixel count is always required. However, since the size of a chip is restricted by mounting constraints on the solid-state imaging device, in order to accommodate the increase in pixel count, responding through miniaturization of pixel size is common. In addition, since the circuit size of a peripheral circuit increases in order to support the increase in pixel count, the number of electrical wiring 3 also increases and, as such, the distance from the light-receiving element 6 to the microlens 57 increases. Specifically, with the increase in pixel count, the aspect ratio, which is the ratio between the distance from the light-receiving element 6 to the microlens 57 and the size of the microlens 6, increases, and oblique incident light cannot be efficiently introduced to the microlens 6.

Furthermore, since the solid-state image sensor is configured of two-dimensionally arranged pixels, the incidence angle of incident light having a spread angle is different between central pixels and peripheral pixels. As a result, there arises the problem that the light-collecting efficiency of the peripheral pixels decreases as compared to the central pixels.

With the increase in incidence angles such as that described above, a lens design that is compliant with the incidence angle is necessary in order to prevent reduced sensitivity in the solid-state image sensor. However, despite an extremely fine construction in which the pixel size in current solid-state image sensors is 2.2 μm, minuter cell sizes are necessary in the future in order to increase pixel count. As such, fabrication of microlenses is on a sub-micron order and the forming process becomes complicated.

Conventionally, various improvement techniques concerning microlenses and color filters have been presented in response to the problems in such solid-state image sensors (see Patent Reference 1: Japanese Unexamined Patent Application Publication No. 2006-351972, Patent Reference 2: Japanese Unexamined Patent Application Publication No. 64-003603, Patent Reference 3: Japanese Unexamined Patent Application Publication No. 4-093801, Patent Reference 4: Japanese Unexamined Patent Application Publication No. 5-206429, Patent Reference 5: Japanese Unexamined Patent Application Publication No. 10-200083, Patent Reference 6: Japanese Patent No. 3189666, Patent Reference 7: Japanese Unexamined Patent Application Publication No. 2000-285821, Patent Reference 8: Japanese Unexamined Patent Application Publication No. 2004-151313, and Non-Patent Reference 1: Kinouseiganryou To Nanotekunoroji (Functional Pigments and Nanotechnology)/supervisor: Seishiro Ito/CMC Publishing, 2006).

Patent Reference 1 proposes a distributed refractive index lens capable of obtaining the same results by discretizing a refractive index distribution at a region that is about half of the wavelength of incident light. With the structure of such lens, it is possible to provide the light-collecting properties of both a refractive index distribution lens and a film-thickness distribution lens, and light-gathering efficiency can be further increased in comparison to the conventional refractive index distribution lens.

Patent References 2, 3, 4, and 5 propose methods for performing light-collection and light-dispersion using the same element.

Patent References 6, 7, 8 and Non-Patent Reference 1 propose a color filter using metallic microparticles.

However, with the technique in Patent Reference 1, although a refractive index distribution lens with high light-collecting efficiency is realized, aside from the lens for light-collection of incident light, a color filter for light-dispersion is required between the lens and the light-receiving element. Sensitivity to oblique incident light decreases since the distance from the lens to the light-receiving element increases by the amount taken up by the color filter, and mixing-in of signal charge to an adjacent photoelectric conversion region which is an adjacent pixel, or to a charge transmission unit occurs due to the light-collected light closing-in on the aperture-end of the light-shielding film.

Furthermore, although the technique in Patent Reference 2 proposes an orthogonal diffraction grating, a diffraction grating having a linear Fresnel lens which combines with a part of a lens for light-collection, and a diffraction grating of regular pitch for light-dispersion must be formed, and thus an extremely complicated manufacturing method is required.

Furthermore, with the technique in Patent Reference 3, after lens formation, the lens for each pixel needs to be dyed for each color in a separate process, and thus an extremely complicated manufacturing method is required.

Furthermore, with the technique in Patent Reference 4, a mask in the shape of the lens is first formed, and the color filter is etched and made into the lens shape by using such mask, and thus an extremely complicated manufacturing method is required.

Furthermore, with the technique in Patent Reference 5, color filter resist formation and lens formation need to be repeated for each color and thus an extremely complicated manufacturing method is required.

Furthermore, in the methods disclosed in Patent References 2 to 5, since lens formation is performed through thermal processing, a resin material which softens with thermal processing is selected as a filter material, and thus high-temperature resistance required for outdoor usage and ultraviolet light resistance due to decomposition of organic material become problems.

Furthermore, although the respective techniques in Patent References 6 and 7 propose a pigment particle color filter, an organic light-sensing base is necessary for filter formation by lithography, and thus ultraviolet light resistance becomes a problem.

In addition, although the respective techniques in Patent Reference 8 and Non-Patent Reference 1 propose a filter in which metallic nanoparticles are dispersed in the resin, the specific method for implementing arbitrary light-dispersion properties such as blue and green is not disclosed.

Meanwhile, since improvement of picture quality in solid-state imaging devices is demanded in recent years, increasing pixel count and improving color reproducibility is required. In response to such a requirement, in the solid-state imaging devices according to the above-described conventional techniques, lenses and color filters are formed separately, and color filters made of organic material are used, and thus, when pixels are miniaturized, light-collecting efficiency for oblique incident light deteriorates and color-selectivity for the color filters is reduced, and thus color reproducibility is reduced. Specifically, with the configuration of the conventional techniques, there is the problem that pixel count-increasing and color reproducibility cannot be combined.

### SUMMARY OF THE INVENTION

The present invention is conceived in view of the aforementioned problems and has as an object to provide a solid-state image sensor that has a high pixel count and includes color filters having high color-reproducibility.

In order to achieve the aforementioned object, the solid-state image sensor in the present invention is a solid-state image sensor including: light-collecting elements each of which is a medium containing dispersant particles; light-receiving elements each of which is provided for a corresponding one of the light-collecting elements, and which receives light collected by the corresponding one of the light-collecting elements and generates an electric signal; and electrical wiring for transferring the electric signal, wherein each of the light-collecting elements has one of plural light-dispersion functions that are different depending on the corresponding light-receiving elements. By doing so, even with minute pixels, the distance from the light-collecting element to the lens can be shortened, light-collecting efficiency for oblique incident light is increased, resolution and sensitivity is increased, and thus a solid-state image sensor having a high pixel count and high color reproducibility can be realized. By performing light-collection and light-dispersion using the same element, incident light outside the regions to be transmitted through the lens is absorbed by the lens material, and thus the reflection of light of a region outside the selected-transmissive-light off of the lens surface due to the refractive index of the lens material being greater than that of air, is suppressed and deterioration of color reproducibility is prevented.

Here, it is preferable that the medium transmits 50% or more of infrared light included in visible light received by the solid-state image sensor having a refractive index of 1.4 or greater, and contains the dispersant particles that are between 5 nm and 50 nm in diameter. By doing so, an excellent light-dispersion property can be realized by plasmon absorption through the coupling of surface plasmon of particles including metal of a small particle diameter, and through metal or metal oxide electron transition absorption.

Furthermore, the light-collecting elements may include a first-type light-collecting element, a second-type light-collecting element, and a third-type light-collecting element, the first-type light collecting element containing at least gold, copper, chromium, or iron-chromium oxide as the dispersant particles, the second-type light-collecting element containing at least cobalt-titanium-nickel-zinc oxide, cobalt-titanium oxide, nickel-titanium-zinc oxide, or cobalt-zinc oxide as the dispersant particles, and the third-type light-collecting element containing at least cobalt-aluminum oxide, or cobalt-chromium oxide as the dispersant particles. By doing so, the particles including metal are homogenously dispersed without clumping together in the medium, and it is possible to realize excellent color reproducibility without color-variances between pixels. Furthermore, a transmitting filter mainly for the red color region is realized when dispersant particles of the first type are used, a transmitting filter mainly for the green color region is realized when dispersant particles of the second type are used, and a transmitting filter mainly for the blue color region is realized when dispersant particles of the third type are used. Furthermore, by mixing the dispersant particles of the first, second, and third types and selecting the percentages thereof, light-dispersion properties for arbitrary regions are realized.

Furthermore, each of the light-collecting elements may contain the dispersant particles composed of at least one type of organic molecules. With such organic molecules, light-dispersion properties for arbitrary regions are realized.

Furthermore, each of the light-collecting elements may have a convex shape. By doing so, the manufacturing process becomes easy.

Furthermore, it is preferable that each of the light-collecting elements has an effective refractive index distribution of a light-transmitting film having concentric structural elements each having a line-width that is comparable to or shorter than a wavelength of incident light to be collected. By doing so, a solid-state image sensor having a high light-collecting efficiency for oblique incident light is realized.

Furthermore, each of the light-collecting elements may be covered by a light-transmitting film having a refractive index different from a refractive index of the medium, and which transmits 50% or more of infrared light included in visible light. By doing so, the light-dispersion property is improved.

Furthermore, it is preferable that the light-transmitting film contains dispersant particles including a metal. By doing so, the light-transmitting film can also possess a light-dispersing function.

Furthermore, the dispersant particles contained in the medium and the dispersant particles contained in the light-transmitting film include a same metal. By doing so, light-dispersion of the same property can be realized on all the regions of the lens and thus it is possible to have both a light-dispersion function and a light-collection function.

Furthermore, it is preferable that each of the light-collecting elements has a concentric distribution of wavelength dependence of an absorption property. By optimizing the transmissivity between the central portion and the peripheral portion of the lens, a solid-state image sensor having a high light-collecting efficiency is realized.

Furthermore, the medium may contain silicon and oxygen. By constructing using such an inorganic material, a lens having excellent heat resistance and ultraviolet light resistance is realized.

Furthermore, the medium may transmit 50% or more of infrared light included in visible light received by the solid-state image sensor which has a refractive index of 1.7 or greater, and a topmost layer of the light-collecting element may be covered by the medium. By doing so, a refractive index distribution lens is easily realized.

Furthermore, each of the light-collecting elements may have a refractive index distribution that is different depending on the corresponding light-receiving elements. By doing so, the focus position can be set to the light-receiving elements, even with lenses using materials having different refractive indexes.

Furthermore, it is preferable that unevenness among surfaces of adjacent ones of the light-collecting elements is less than 50% of a central wavelength of light in a height direction of the solid-state image sensor, the light being transmitted by the light-collecting elements. By doing so, color-mixing due to oblique incident light transmitted by an adjacent filter is prevented.

Furthermore, an upper portion of each of the light-collecting elements may be covered by a material having a lower refractive index than the medium. By doing so, reflection from the light-collecting element surface is prevented.

Furthermore, it is preferable that the light-collecting elements are separated by a material which is provided between adjacent ones of the light receiving elements and absorbs 50% or more of infrared light included in visible light. By doing so, color-mixing due to oblique incident light transmitted by an adjacent filter is prevented.

Furthermore, each of the light receiving elements has a reflectance from visible light to infrared light of 15% or less. By doing so, straying-in of light reflected from the lens is prevented.

Furthermore, it is preferable that the light-collecting elements are insulated from the light-receiving elements and the electrical wiring. By doing so, conduction to an unintended place by a light-collecting element or electrical wiring is prevented.

Furthermore, both the medium and the dispersant particles may be composed of inorganic material.

Furthermore, the present invention can be implemented, not only as a solid-state image sensor as that described above, but also as a manufacturing method thereof, that is, a method for manufacturing a solid-state image sensor, the method including: forming, on a substrate, a semiconductor circuit including light-receiving elements, electrical wiring, a light-shielding layer, signal transmission units, and an antireflection film; forming color separators on the formed semiconductor circuit; forming each of a red color transmitting film, a green color transmitting film, and a blue color transmitting film on corresponding regions enclosed by the formed color separators; and etching or patterning, into a concentric circle shape, the each of the red color transmitting film, the green color transmitting film, and the blue color transmitting film that have been formed.

According to the present invention, by forming the lens and filter in the same element instead of forming a color filter separately, the height of the solid-state image sensor can be lowered, and a solid-state image sensor including fine pixels of high light-collecting efficiency and having a color filter with high color reproducibility.

Therefore, the practical value of the present invention in these days where small and thin digital cameras are in demand is high.

### FURTHER INFORMATION ABOUT TECHNICAL BACKGROUND TO THIS APPLICATION

The disclosure of Japanese Patent Application No. 2008-098643 filed on Apr. 4, 2008 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a diagram showing the cross-section structure of a solid-state image sensor in a first embodiment of the present invention;

FIG. 2 is a diagram showing the upper surface structure of a distributed refractive index lens in the first embodiment of the present invention;

FIG. 3 is a diagram showing the cross-section structure of the distributed refractive index lens in the first embodiment of the present invention;

FIG. 4 is a diagram showing the basic structure configuring the distributed refractive index lens (regular pitch) in the first embodiment of the present invention;

FIG. 5 is a graph of the sensitivity property of the solid-state image sensor in the first embodiment of the present invention;

FIG. 6 is a graph of the reflectance property of the solid-state image sensor in the first embodiment of the present invention;

FIG. 7 is a diagram showing a manufacturing process of a light-transmitting film in the first embodiment of the present invention;

FIG. 8 is a diagram showing a manufacturing process of light-collecting elements in the first embodiment of the present invention;

FIG. 9 is a diagram showing the cross-section structure of a solid-state image sensor in a second embodiment of the present invention;

FIG. 10 is a graph of the sensitivity property of the solid-state image sensor in the second embodiment of the present invention;

FIG. 11 is a diagram showing a manufacturing process of light-collecting elements in the second embodiment of the present invention;

FIG. 12 is a diagram showing the cross-section structure of a solid-state image sensor in a third embodiment of the present invention;

FIG. 13 is a diagram showing the cross-section structure of a distributed refractive index lens in the third embodiment of the present invention;

FIG. 14 is a graph of the reflectance property of the solid-state image sensor in the third embodiment of the present invention;

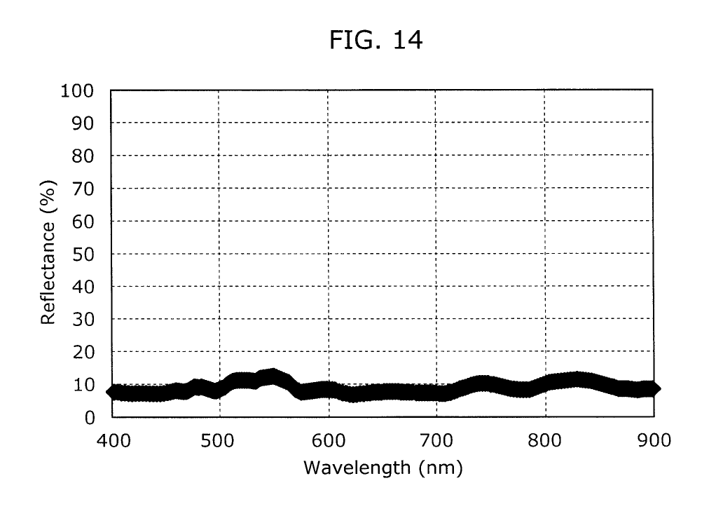

FIG. 15 is a diagram showing a manufacturing process of the distributed refractive index lens in the third embodiment of the present invention;

FIG. 16 is a diagram showing the cross-section structure of a solid-state image sensor in a fourth embodiment of the present invention;

FIG. 17 is a diagram showing a manufacturing process of the distributed refractive index lens in the fourth embodiment of the present invention;

FIG. 18 is a diagram showing the cross-section structure of a solid-state image sensor in a fifth embodiment of the present invention;

FIG. 19 is a diagram showing a manufacturing process of the distributed refractive index lens in the fifth embodiment of the present invention;

FIG. 20 is a diagram showing the cross-section structure of a solid-state image sensor in a sixth embodiment of the present invention;

FIG. 21 is a diagram showing the cross-section structure of a solid-state image sensor in a seventh embodiment of the present invention; and

FIG. 22 is an example of the basic structure of a conventional solid-state image sensor.

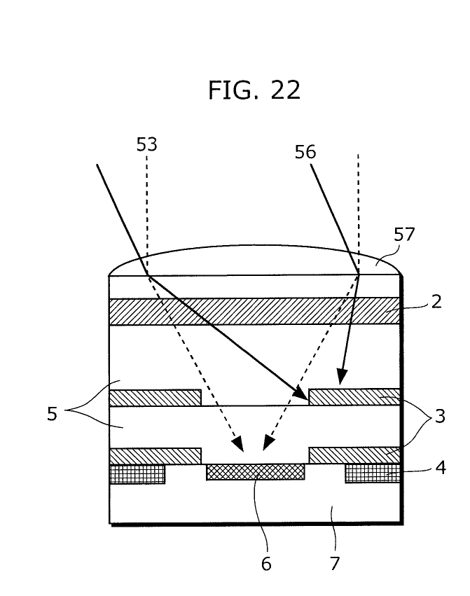

### DESCRIPTION OF THE PREFERRED EMBODIMENT(S)

Hereinafter, embodiments of the present invention shall be specifically described with reference to the Drawings. It should be noted that, although the following embodiments and the attached Drawings are used to describe the present invention, they are provided as examples, and the present invention is not intended to be limited to such.

### First Embodiment

First, a solid-state image sensor in a first embodiment shall be described.

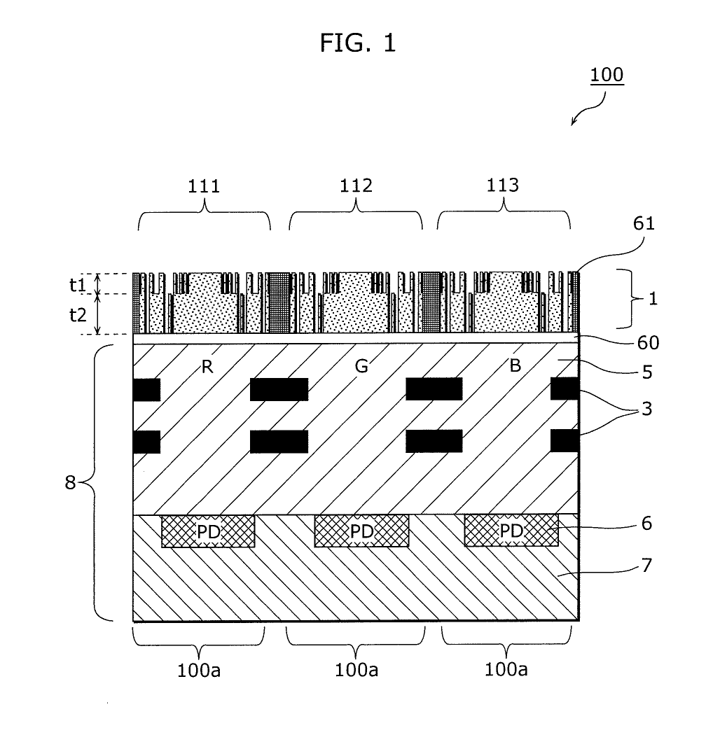

FIG. 1 is a diagram showing the basic structure of a solid-state image sensor 100 in the present embodiment. As shown in FIG. 1, the solid-state image sensor 100 is an assembly of two-dimensionally arranged pixels 100a that are 2.25 square μm in size, and includes distributed refractive index lenses 1, color separators 61, an antireflection film 60, electrical wiring 3 which also serves as a light-shielding film, an inter-layer insulating film 5, light-receiving elements (Si photodiodes) 6, and a Si substrate 7 (it should be noted that, as shown in FIG. 1, the portion from the electrical wiring 3 to the Si substrate 7 is also called a “semiconductor integrated circuit 8”). Each of the light-receiving elements 6 receives light collected by a corresponding one of the refractive index lenses 1 and generates an electric signal. The electrical wiring 3 transfer the electric signals from the light-receiving elements 6.

The distributed refractive index lenses 1 are provided with the functions of both a microlens (that is, a light-collecting function) and a color filter (that is, a light-dispersion function), and are configured of light-collecting elements (a red color transmitting region 111, a green color transmitting region 112, and a blue color transmitting region 113) corresponding to the regions of light that are transmitted.

In order to implement the light-dispersion function corresponding to the aforementioned three colors, particles which include metal and are equal to or less than 100 nm in particle diameter are dispersed in each of the distributed refractive index lenses 1. In the present embodiment, inorganic particles are used as dispersant particles. Specifically, gold of a 5 nm to 50 nm (median value: 15 nm) particle diameter distribution, cobalt-titanium-nickel-zinc oxide of a 5 nm to 50 nm (median value: 25 nm) particle diameter distribution, and cobalt-aluminum oxide of a 5 nm to 50 nm (median value: 20 nm) particle diameter distribution are dispersed in silicon oxide for the red color transmitting region 111, the green color transmitting region 112, and the blue color transmitting region 113, respectively. It should be noted that silicon oxide (refractive index n=1.45) is an example of a medium which transmits 50% or more of infrared light from the visible light that is light-received by the solid-state image sensor 100 with a refractive index of 1.4 or greater. Specifically, silicon oxide is an example of a transparent inorganic medium that can provide a light-collecting function.

It should be noted that, each of the distributed refractive index lenses 1 is electrically insulated from the corresponding electrical wiring 3 by the inter-layer insulating film 5 and the antireflection film 60 in which silicon nitride films are stacked above and below a silicon oxynitride film.

The color separators 61, provided between adjacent light-collecting elements (the red color transmitting region 111, the green color transmitting region 112, and the blue color transmitting region 113), prevent light from leaking between the adjacent light-collecting elements and are made of a material which absorbs 50% or more of the infrared light from visible light. In such material, copper oxide of a 5 nm to 50 nm (median value: 25 nm) particle diameter distribution is dispersed in silicon oxide as dispersant particles.

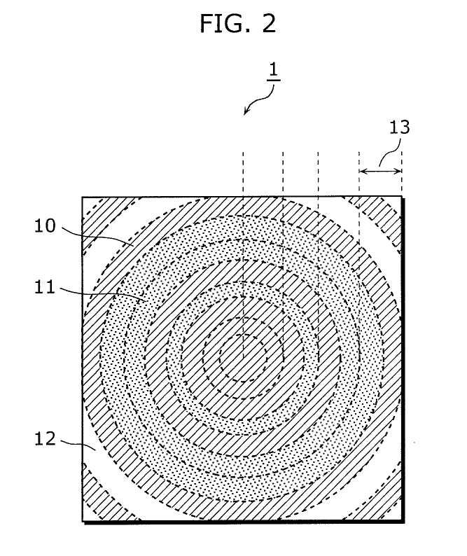

FIG. 2 is a diagram showing a top-view of one of the distributed refractive index lenses 1 in the above-described FIG. 1. The distributed refractive index lens 1 is made of two materials of different refractive indexes, and which cross section (top plane) traversing the light axis is a concentric circle structure. As shown in FIG. 1, the concentric circle structure of the distributed refractive index lens 1 is a two-staged concentric circle structure in which film thickness is 0.4 μm (t1) and 0.8 μm (t2). It should be noted that, here, the top-stage and bottom-stage concentric circle structure are defined as top-stage and bottom-stage light-transmitting films. In FIG. 2, a portion 10 having a film thickness of 1.2 μm is indicated with “hatching” and a portion 11 having a film thickness of 0.8 μm is indicated with a “dot pattern”. It should be noted that a portion 12 (air in the present embodiment) having a film thickness of 0 μm is indicated with “no-pattern: white”. Furthermore, the distributed refractive index lens 1 in the present embodiment is a columnar structure (or a cylindrical structure) in which a concentric pattern is engraved in silicon oxide so that zone region widths 13 to be described later have an regular pitch (0.2 μm here), and the surrounding medium is air (refractive index n=1).

Here, the region forming the distributed refractive index lens 1 is in a square shape to match the aperture of the respective pixels. Generally, since gaps are formed in between lenses when the region of the incidence aperture is circular, leaking light arises and becomes a cause for increasing light-collection loss. However, when the region of the incidence aperture is made into a square-shape, light-collecting of incident light is possible on all regions of the pixel, and thus leaking light is eliminated and light-collection loss can be reduced.

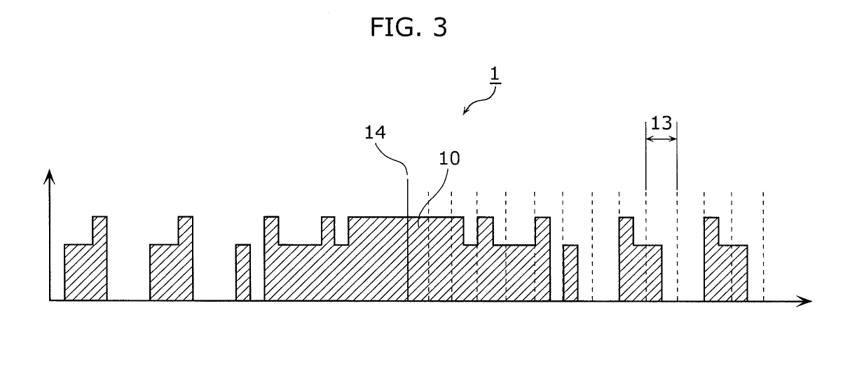

FIG. 3 is a diagram showing an example of a more detailed cross-section of one of the distributed refractive index lenses 1 in the present embodiment. In a typical distributed refractive index lens, the refractive index is highest at the optical center. As shown in FIG. 3, even in the case of the present embodiment, silicon oxide is densely gathered in the vicinity of an optical center 14 and becomes sparser towards the outer zone regions. At this time, when each zone region width (hereafter called “line width”) 13 is comparable to or less than the wavelength of incident light, the effective refractive index in which light is sensed is determined by the volume ratio of a high-refractive index material (silicon oxide in the present embodiment) and a low-refractive index material (air in the present embodiment) in such zone region. In other words, the effective refractive index increases when the high-refractive index material in the zone region is increased, and the effective refractive index decreases when the high-refractive index material in the zone region is decreased.

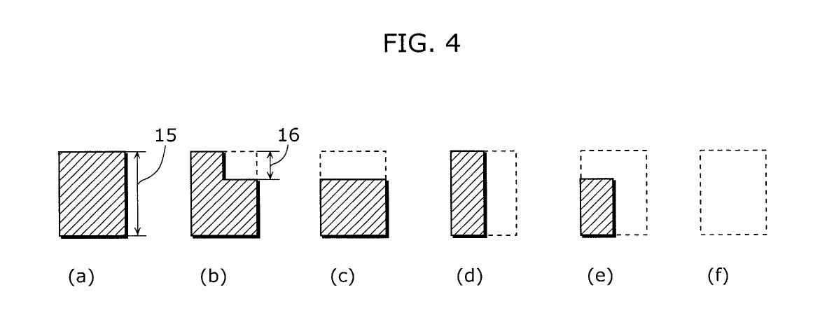

FIG. 4, including (a) to (f), is a diagram showing basic patterns of the volume ratio between the high-refractive index material and the low-refractive index material in each zone region of the two-staged concentric circle structure (a cross section of a basic structure configuring one zone region). (a) in FIG. 4 is the densest structure, that is, the structure in which the effective refractive index is highest. The effective refractive index decreases going from (b) to (f) in FIG. 4. At this time, the top-stage film thickness t1 (15) on the light incidence-side and the bottom-stage film thickness t2 (16) on the substrate-side are 0.4 μm and 0.8 μm, respectively, and the film thickness ratio (top-stage/bottom-stage) is 0.5. Here, by changing the above-described volume ratio, the effective refractive index can be controlled. For example, when the volume ratio is made high, the volume decrease in the high-refractive index material due to the change in the basic structure (a) in FIG. 4→(f) in FIG. 4 is large, and thus the decrease in the refractive index in a region having a high effective refractive index becomes big. On the other hand, when the volume ratio is made low, the volume decrease in the high-refractive index material is small, and thus the decrease in the refractive index in a region having a low effective refractive index becomes small.

It should be noted that although a basic structure such as that shown in (a) to (f) in FIG. 4 is given as an example in order to facilitate description in the present embodiment, other structures may also be used. For example, it is possible to use a convex structure combining (c) and (b) in FIG. 4, and use a concave structure combining (b) and (d) in FIG. 4, as a basic structure. At this time, when these are adopted as the basic structure in a region that is about half the wavelength of incident light, the same light-collecting property can be obtained.

Since different particles are dispersed in each of the red color transmitting region 111, the green color transmitting region 112, and the blue color transmitting region 113 in such distributed refractive index lenses 1, the respective refractive indices of the materials for forming the distributed refractive index lenses 1 are different. As such, in order to match a focus position of each of the distributed refractive index lens 1 to the corresponding light-receiving element 6, formation must be carried out so that silicon oxide becomes sparse in a region having a high refractive index, and silicon oxide becomes dense in a region having a low refractive index, as disclosed in Patent Reference 1.

Furthermore, since each of the distributed refractive index lenses 1 are configured of a medium (high-refractive index material) of a concentric structure having line widths that are each comparable to or shorter than the wavelength of incident light, formation using conventional pigment material of micron-level particle diameters is not possible since these are larger than the line widths.

It should be noted that each of the distributed refractive index lenses 1 is electrically insulated from the corresponding light-receiving element 6 and electrical wiring 3 by the inter-layer insulating film 5.

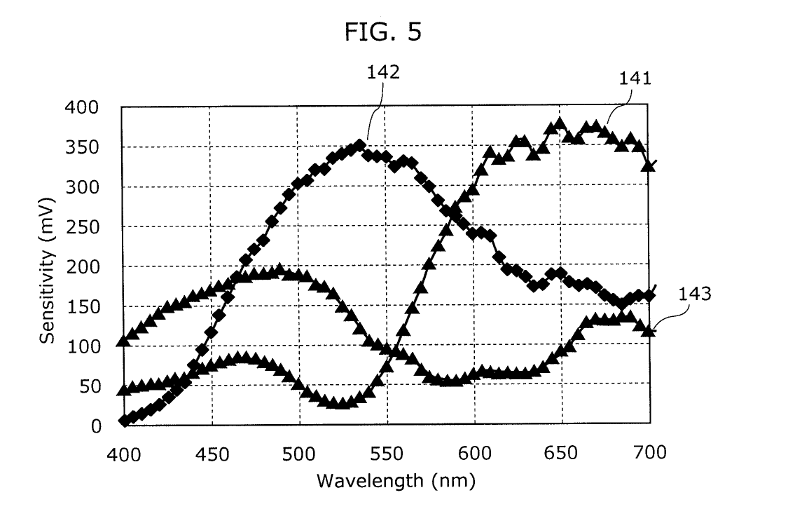

FIG. 5 is a diagram showing the light-collecting sensitivity properties (sensitivity property 141 of a red color transmitting region pixel, sensitivity property 142 of a green color transmitting region pixel, and sensitivity property 143 of a blue color transmitting region pixel) of the solid-state image sensor 100 in the present embodiment. In the diagram, as can be seen from the three curves which are the peaks of the respective central wavelengths of the three colors, the solid-state image sensor 100 in the present embodiment has excellent light-dispersion properties in the red region, the green region, and the blue region.

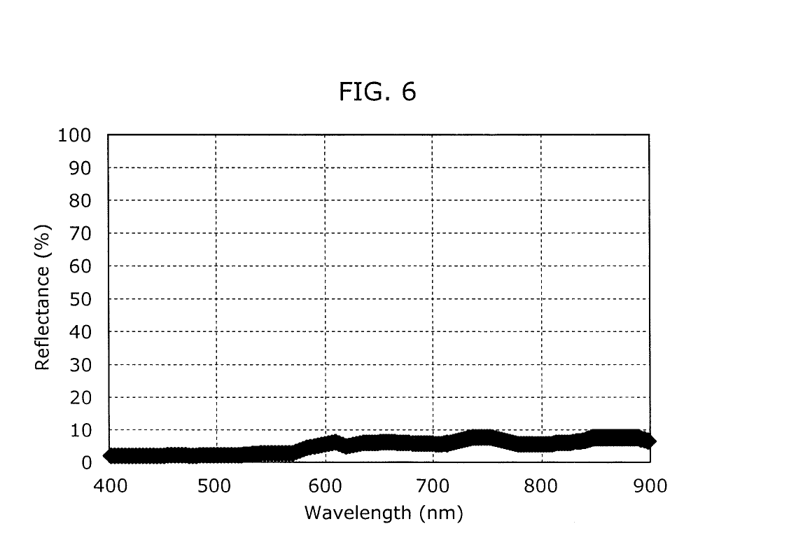

FIG. 6 is a diagram showing the reflective property of a solid-state image sensor 100 in the present embodiment. In the transmitting regions of all three colors, reflectance is a low value of 10% or less.

With the present embodiment, it is possible to implement a solid-state image sensor that has a high pixel count and includes a color filter having high color reproducibility.

### Manufacturing Method in the First Embodiment

Next, a method for manufacturing the solid-state image sensor 100 in the present embodiment shall be described.

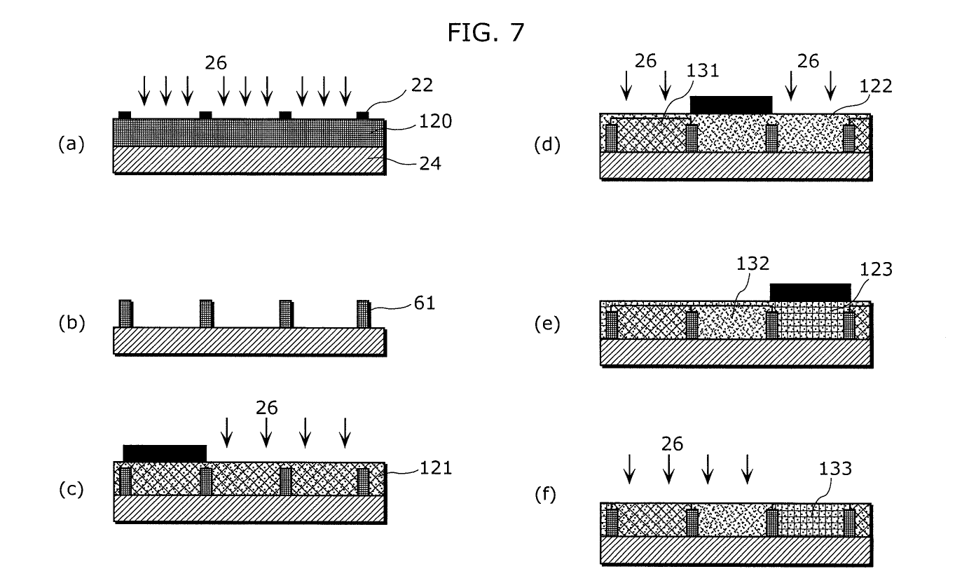

FIG. 7, including (a) to (f), is a diagram showing the manufacturing process for the solid-state image sensor 100 in the present embodiment.

First, a semiconductor integrated circuit 24, which includes light-receiving elements, wiring, a light-shielding layer, signal transmission units, and an antireflection layer, is formed on a Si substrate using the normal semiconductor process. The size of one pixel is, for example, 2.25 square μm, and the light-receiving unit is 1.5 square μm.

Next, as shown in (a) to (f) in FIG. 7, the color separators 61, a red color transmitting film 131, a green color transmitting film 132, and a blue color transmitting film 133 are formed on the semiconductor integrated circuit 24.

Specifically, first, a copper oxide particle solution dispersed in a SOG (Spin coating On Glass) solution is applied on the semiconductor integrated circuit 24 by spin-on and then fired at 400 degrees Celsius to form a light-absorbing material 120. A resist 22 is applied on the light-absorbing material 120. Subsequently, patterning of the resist 22 is performed using light exposure ((a) in FIG. 7, up to this point).

After developing, the color separators 61 are formed by etching 26 using dry etching and wet etching, and the resist is removed ((b) in FIG. 7).

Next, a gold particle solution dispersed in a SOG solution is applied by spin-on and provisionally fired at 250 degrees Celsius to form a red color transmitting material 121, and after a resist is applied, patterning of the resist is performed using light exposure again ((c) in FIG. 7). The red color transmitting film 131 is formed through dry etching and wet etching, the resist is removed, and firing at 400 degrees Celsius is performed.

Next, a cobalt-titanium-nickel-zinc oxide particle solution dispersed in a SOG solution is applied by spin-on and provisionally fired at 250 degrees Celsius to form a green color transmitting material 122, and after a resist is applied, pattering of the resist is performed using light exposure again ((d) in FIG. 7). The green color transmitting film 132 is formed through dry etching and wet etching. Here, since the dry etching rate and the wet etching rate of the red color transmitting film 131 which is fired at 400 degrees Celsius is low compared to the green color transmitting material 122 which is not sufficiently crystallized by being fired at only 250 degrees Celsius, the red color transmitting film 131 is substantially unetched. Subsequently, the resist is removed and firing at 400 degrees Celsius is performed.

Next, a cobalt-aluminum oxide particle solution dispersed in a SOG solution is applied by spin-on and provisionally fired at 250 degrees Celsius to form a blue color transmitting material 123, and after a resist is applied, patterning of the resist is performed using light exposure again ((e) in FIG. 7). The blue color transmitting film 133 is formed through dry etching and wet etching. Here, since the dry etching rate and the wet etching rate of the red color transmitting film 131 and the green color transmitting film 132 which are fired at 400 degrees Celsius is low compared to the blue color transmitting material 123 which is not sufficiently crystallized by being fired at only 250 degrees Celsius, the red color transmitting film 131 and the green color transmitting film 132 are substantially unetched.

Subsequently, the resist is removed and the firing at 400 degrees Celsius is performed ((f) in FIG. 7).

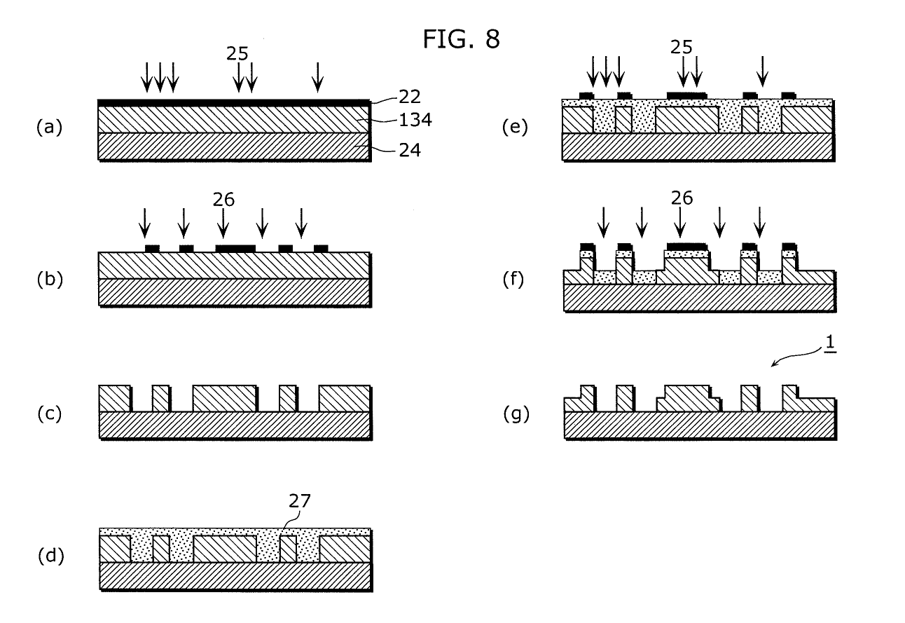

FIG. 8, including (a) to (g), is a diagram showing a process for manufacturing one of the distributed refractive index lenses 1 on an arbitrary light-transmitting film 134. Although a process of manufacturing on only one type of light-transmitting film 134 is illustrated in FIG. 8 for the sake of simplicity, the distributed refractive index lenses 1 are formed simultaneously for the red color transmitting film 131, the green color transmitting film 132, and the blue color transmitting film 133. The distributed refractive index lens 1 assumes a two-staged concentric circle structure, and its formation is carried out by performing photolithography and etching twice. The resist 22 is applied on the light-transmitting film 134. Subsequently, patterning of the resist 22 is performed using the light exposure 25 ((a) in FIG. 8, up to this point). It should be noted that the thickness of the light-transmitting film (here, a silicon oxide film) 134 and the resist 22 are 1.2 μm and 0.5 μm, respectively.

After developing, the etching 26 using dry etching and wet etching is performed ((b) in FIG. 8), and a fine structure is formed on the pixel surface ((c) in FIG. 8). After removing the resist 22, a BARC 27 is implanted and flattened ((d) in FIG. 8). After a resist is applied, patterning is performed using the light exposure 25 again ((e) in FIG. 8). After etching by dry etching and wet etching ((f) in FIG. 8), the lens in the present invention is formed by removing the resist and the BARC ((g) in FIG. 8).

It should be noted that although formation of a lens having a two-staged concentric circle structure is attempted in the present embodiment, it is possible to construct a lens with further stages (that is 3 stages or more) by using the process which combines photolithography and etching as shown in (a) to (g) in FIG. 8. As the number of stages increases, the number of degrees in the grayscale of the refractive index distribution increases, and thus light-collection efficiency improves.

It should be noted that the distributed refractive index lenses 1 may be formed using nanoimprinting.

It should be noted that although gold is exemplified as a particle for dispersing in the red color transmitting region 111, a material including copper, chromium or iron-chromium oxide may be used in place of or together with gold. Furthermore, although cobalt-titanium-nickel-zinc oxide is exemplified as a particle for dispersing in the green color transmitting region 112, a material including cobalt-titanium oxide, nickel-titanium-zinc oxide or cobalt-zinc oxide may be used in place of or together with cobalt-titanium-nickel-zinc oxide. Furthermore, although cobalt-aluminum oxide is exemplified as a particle for dispersing in the blue color transmitting region 113, a material including cobalt-chromium oxide may be used in place of or together with cobalt-aluminum oxide.

It should be noted that although a solid-state image sensor having three types of light-transmitting regions is exemplified in the first embodiment, it is also acceptable to form other types of light-transmitting regions in which particles made of at least two types among the following are mixed: gold, copper, chromium, iron-chromium oxide, cobalt-titanium-nickel-zinc oxide, cobalt-titanium oxide, nickel-titanium-zinc oxide, cobalt-zinc oxide, cobalt-aluminum oxide, and cobalt-chromium oxide.

It should be noted that although silicon oxide is exemplified as one material composing the distributed refractive index lenses 1, silicon nitride, titanium oxide, or tantalum oxide, which are high-refractive index materials, is also acceptable.

It should be noted that although a material in which copper oxide particles are dispersed in silicon oxide is exemplified as a material composing the color separators 61, silicon nitride, titanium oxide, or tantalum oxide may be used in place of silicon oxide, and particles of tin oxide or cobalt oxide may be dispersed in such medium in place of copper oxide.

As described above, according to the solid-state image sensor 100 in the present embodiment, since light-collection and light-dispersion are performed in the same element, the distance between the light-receiving element and the microlens is reduced and the aspect ratio is controlled thereby facilitating increasing pixel count, and, since incident light outside the regions to be transmitted through the lens is absorbed by the lens material, the reflection of light of a region outside the selected-transmissive-light off of the lens surface due to the refractive index of the lens material being greater than that of air, is suppressed, and thus high color reproducibility is ensured. With this, a solid-state image sensor having a high pixel count and including color filters having high color reproducibility is realized.

### Second Embodiment

Next, a solid-state image sensor in a second embodiment shall be described.

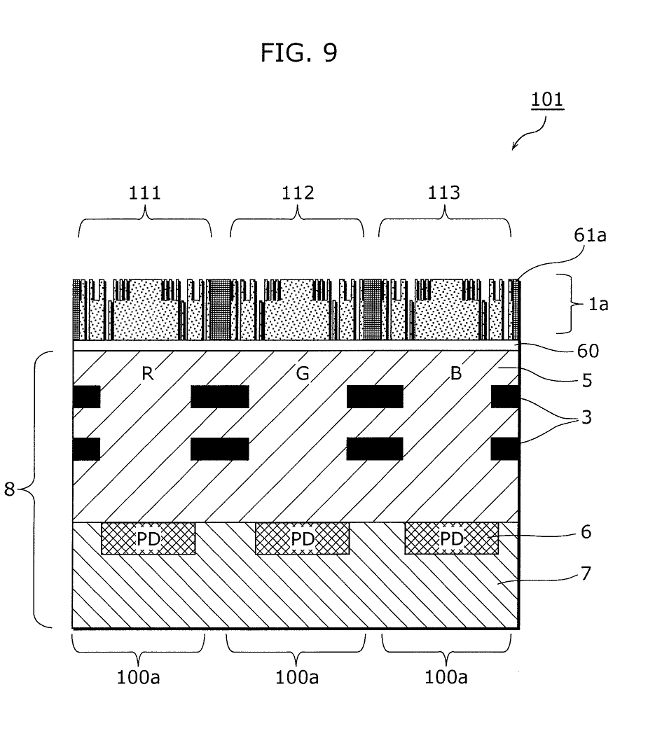

FIG. 9 is a diagram showing the basic structure of a solid-state image sensor 101 in the present embodiment. As shown in FIG. 9, the solid-state image sensor 101 is an assembly of the two-dimensionally arranged pixels 100a that are 2.25 square μm in size, and includes distributed refractive index lenses 1a, color separators 61a, the antireflection film 60, the electrical wiring 3, the inter-layer insulating film 5, the light-receiving elements (Si photodiodes) 6, and the Si substrate 7 (it should be noted that, as shown in FIG. 9, the portion from the electrical wiring 3 to the Si substrate 7 is also called the “semiconductor integrated circuit 8”). Each of the light-receiving elements 6 receives light collected by a corresponding one of the refractive index lenses 1 and generates an electric signal. The electrical wiring 3 transfer the electric signals from the light-receiving elements 6.

The solid-state image sensor 101 in the present embodiment has basically the same structure as that in the first embodiment, but is different from the first embodiment in the material of the distributed refractive index lenses 1a (particles made of organic molecules are dispersed in an organic medium) and the material of the color separators 61a. Hereinafter, constituent elements that are the same as those in the first embodiment are given the same reference numerals, and description shall be centered on the points of difference from the first embodiment.

The distributed refractive index lenses 1 are provided with the functions of both a microlens (that is, a light-collecting function) and a color filter (that is, a light-dispersion function), and are configured of light-collecting elements (a red color transmitting region 111, a green color transmitting region 112, and a blue color transmitting region 113) corresponding to the regions of light that are transmitted.

In order to implement the light-dispersion function corresponding to the aforementioned three colors, particles which include metal and are equal to or less than 100 nm in particle diameter are dispersed in each of the distributed refractive index lenses 1a. In the present embodiment, particles made of organic molecules including metal are used as dispersant particles. Specifically, anthraxylene (PR177) of a 20 nm to 100 nm (median value: 50 nm) particle diameter distribution, copper phthalocyanine chlorobromide of a 20 nm to 100 nm (median value: 75 nm) particle diameter distribution, and ε-copper phthalocyanine of a 20 nm to 100 nm (median value: 20 nm) particle diameter distribution, are dispersed in a transparent resin such as acrylic or polycarbonate or polystyrene, for the red color transmitting region 111, the green color transmitting region 112, and the blue color transmitting region 113, respectively. It should be noted that the transparent resin (acrylic having a refractive index n=1.5, polycarbonate having a refractive index n=1.59, polystyrene having a refractive index of 1.6) is an example a medium which transmits 50% or more of infrared light from the visible light that is light-received by the solid-state image sensor 101 with a refractive index of 1.4 or greater. Specifically, the transparent resin is an example of a transparent organic medium that can provide a light-collecting function.

The color separators 61a, provided between adjacent light-collecting elements (the red color transmitting region 111, the green color transmitting region 112, and the blue color transmitting region 113), prevent light from leaking between the adjacent light-collecting elements and are made of a material which absorbs 50% or more of the infrared light from visible light. In such material, carbon black of a 5 nm to 50 nm (median value: 25 nm) particle diameter distribution is dispersed in silicon oxide as dispersant particles.

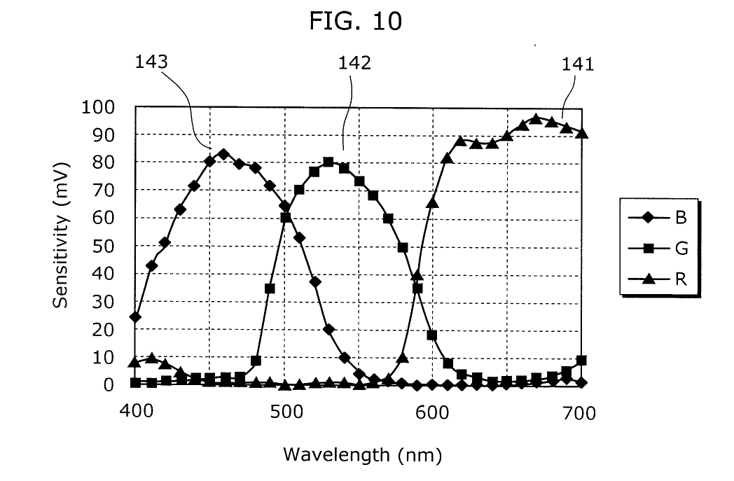

FIG. 10 is a diagram showing the light-receiving sensitivity properties (sensitivity property 141 of a red color transmitting region pixel, sensitivity property 142 of a green color transmitting region pixel, and sensitivity property 143 of a blue color transmitting region pixel) of the solid-state image sensor 101 in the present embodiment. In the diagram, as can be seen from the three curves which are the peaks of the respective central wavelengths of the three colors, the solid-state image sensor 101 in the present embodiment has excellent light-dispersion properties in the red region, the green region, and the blue region.

### Manufacturing Method in the Second Embodiment

Next, a method for manufacturing the solid-state image sensor 101 in the present embodiment shall be described.

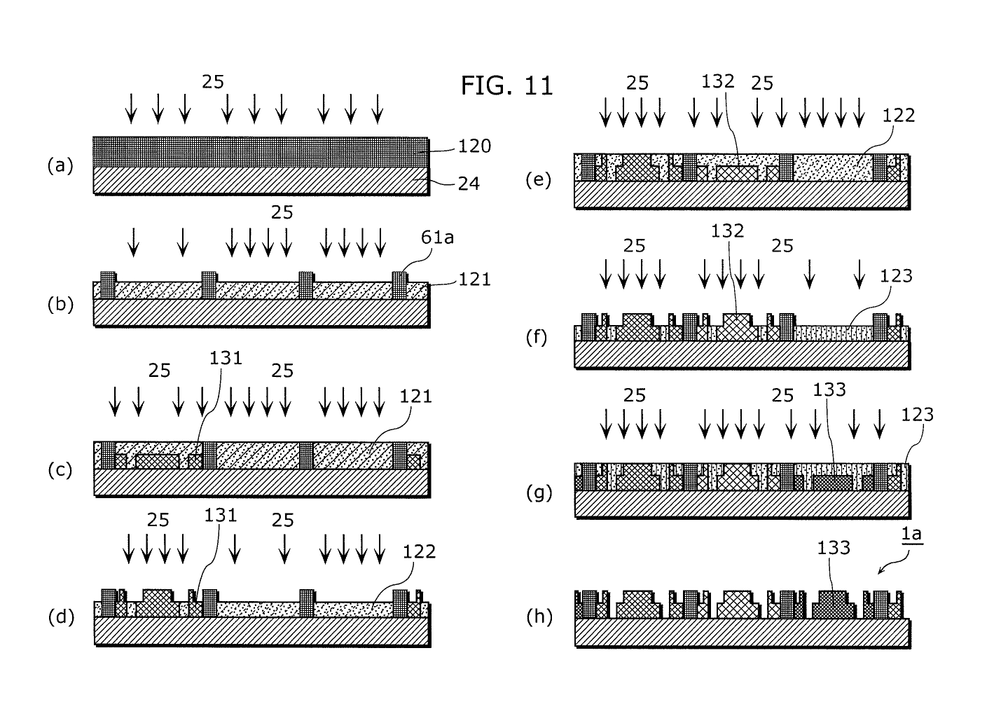

FIG. 11, including (a) to (h), is a diagram showing the manufacturing process for the solid-state image sensor 101 in the present embodiment.

First, the semiconductor integrated circuit 24, which includes light-receiving elements, wiring, a light-shielding layer, signal transmission units, and an antireflection layer, is formed on a Si substrate using the normal semiconductor process. The size of one pixel is 2.25 square μm, and the light-receiving unit is 1.5 square μm.

Next, as shown in (a) to (h) in FIG. 11, the color separator 61a, the red color transmitting film 131, the green color transmitting film 132, and the blue color transmitting film 133 are formed on the semiconductor integrated circuit 24.

First, a photosensitive carbon black particle solution dispersed in a transparent resin such as acrylic or polycarbonate or polyethylene is applied on the semiconductor integrated circuit 24 by spin-on to form the light-absorbing material 120. Subsequently, patterning is performed using the light exposure 25 ((a) in FIG. 11, up to this point). After developing, and forming of the color separators 61a, a photosensitive-anthraxylene solution dispersed in a transparent resin is applied by spin-on to form the red color transmitting material 121, and patterning of the red color transmitting material 121 is performed using the light exposure 25 again ((b) in FIG. 11). In the developing, after the first-stage red color transmitting film 131 is formed, a photosensitive anthraxylene solution dispersed in a transparent resin is applied again by spin-on to form the red color transmitting material 121. Patterning of the red color transmitting material 121 is performed using the light exposure 25 again ((c) in FIG. 11).

In the developing, after the second-stage red color transmitting film 131 is formed, a photosensitive copper phthalocyanine chlorobromide solution dispersed in a transparent resin is applied by spin-on to form the green color transmitting material 122. Patterning of the green color transmitting material 122 is performed using the light exposure 25 again ((d) in FIG. 11).

In the developing, after the first-stage green color transmitting film 132 is formed, a photosensitive copper phthalocyanine chlorobromide solution dispersed in a transparent resin is applied by spin-on to form the green color transmitting material 122. Patterning of the green color transmitting material 122 is performed using the light exposure 25 again ((e) in FIG. 11).

In the developing, after the second-stage green color transmitting film 132 is formed, a photosensitive E-copper phthalocyanine solution dispersed in a transparent resin is applied by spin-on to form the blue color transmitting material 123. Patterning of the blue color transmitting material 123 is performed using the light exposure 25 again ((f) in FIG. 11). In the developing, after the first-stage blue color transmitting film 133 is formed, a photosensitive blue color transmitting material 123 solution dispersed in a transparent resin is applied by spin-on again to form the blue color transmitting material 123. Patterning of the blue color transmitting material 123 is performed using again the light exposure 25 ((g) in FIG. 11).

Subsequently, the second-stage blue color transmitting film 133 is formed by developing, and the red, green, and blue distributed refractive index lenses are formed ((h) in FIG. 11).

It should be noted that the distributed refractive index lenses 1a may be formed using nanoimprinting.

It should be noted that although a transparent resin is exemplified as one material composing the distributed refractive index lenses 1a, silicon oxide, silicon nitride, titanium oxide, or tantalum oxide is also acceptable.

It should be noted that although a material in which carbon black particles are dispersed in a transparent resin is exemplified as a material composing the color separators 61a, silicon oxide, silicon nitride, titanium oxide, or tantalum oxide may be used in place of the transparent resin, and particles of copper oxide, tin oxide or cobalt oxide may be dispersed in such medium in place of carbon black.

As described above, according to the solid-state image sensor 101 in the present embodiment, since light-collection and light-dispersion are performed in the same element, the distance between the light-receiving element and the microlens is reduced and the aspect ratio is controlled thereby facilitating increasing pixel count, and, since incident light outside the regions to be transmitted through the lens is absorbed by the lens material, the reflection of light of a region outside the selected-transmissive-light off of the lens surface is suppressed and thus high color reproducibility is ensured. With this, a solid-state image sensor having a high pixel count and including color filters having high color reproducibility is realized.

Furthermore, in the present embodiment, the distributed refractive index lenses are made of an organic medium and organic dispersant particles, and can be easily manufactured by patterning.

### Third Embodiment

Next, a solid-state image sensor in a third embodiment shall be described.

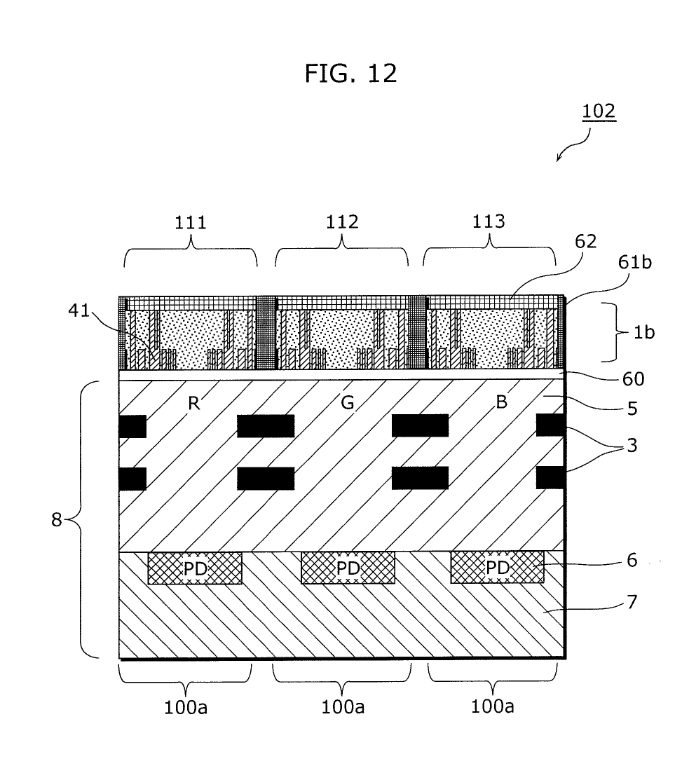

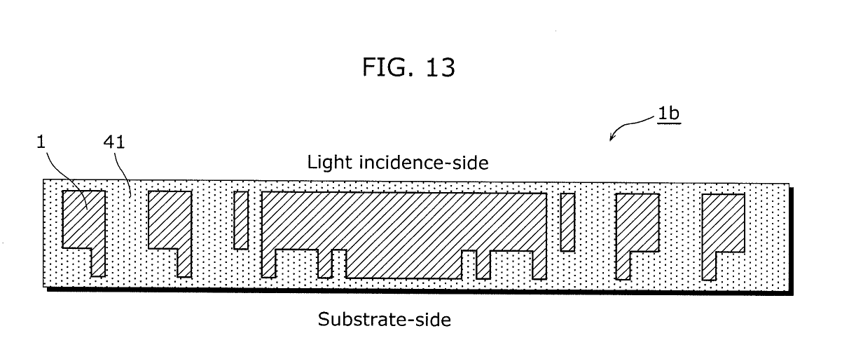

FIG. 12 is a diagram showing a solid-state image sensor 102 including distributed refractive index lenses 1b having a concave structure in the third embodiment, and FIG. 13 is a diagram showing the distributed refractive index lenses 1b having a concave structure. The solid-state image sensor 102 is an assembly of the two-dimensionally arranged pixels 100a, and includes distributed refractive index lenses 1b, color separators 61b, the antireflection film 60, the electrical wiring 3, the inter-layer insulating film 5, the light-receiving elements 6, and the Si substrate 7. Each of the light-receiving elements 6 receives light collected by a corresponding one of the refractive index lenses 1 and generates an electric signal. The electrical wiring 3 transfer the electric signals from the light-receiving elements 6.

The solid-state image sensor 102 in the present embodiment has basically the same structure as that in the first embodiment, but is different from the first embodiment in the material (high-refractive rate material and low-refractive rate material) and structure (convex in the downward direction) of the distributed refractive index lenses 1b and in the material of the color separators 61b. Hereinafter, constituent elements that are the same as those in the first embodiment are given the same reference numerals, and description shall be centered on the points of difference from the first embodiment.

The distributed refractive index lenses 1b are provided with the functions of both a microlens (that is, a light-collecting function) and a color filter (that is, a light-dispersion function), and are configured of light-collecting elements (the red color transmitting region 111, the green color transmitting region 112, and the blue color transmitting region 113) corresponding to the regions of light that are transmitted. In order to implement the light-dispersion function corresponding to the aforementioned three colors, particles which include metal and are equal to or less than 100 nm in particle diameter are dispersed in each of the distributed refractive index lenses 1b. In the present embodiment, as dispersant particles, gold of a 5 nm to 50 nm (median value: 15 nm) particle diameter distribution, cobalt-titanium-nickel-zinc oxide of a 5 nm to 50 nm (median value: 25 nm) particle diameter distribution, and cobalt-aluminum oxide of a 5 nm to 50 nm (median value: 20 nm) particle diameter distribution are dispersed in titanium oxide for the red color transmitting region 111, the green color transmitting region 112, and the blue color transmitting region 113, respectively. It should be noted that titanium oxide (refractive index n=2.5) is an example of a medium which transmits 50% or more of infrared light from the visible light that is light-received by the solid-state image sensor 102 with a refractive index of 1.7 or greater. Specifically, titanium oxide is an example of a transparent inorganic medium that can provide a light-collecting function. The distributed refractive index lens 1b has a structure in which the upside of the distributed refractive index lens 1b is structurally overturned. As a result, the topmost layer of the light-collecting element is covered with a medium which transmits 50% or more of infrared light from the visible light that is light-received by the solid-state image sensor with a refractive index of 1.7 or greater.

The color separators 61b, provided between adjacent light-collecting elements (the red color transmitting region 111, the green color transmitting region 112, and the blue color transmitting region 113), prevent light from leaking between the adjacent light-collecting elements and are made of a material which absorbs 50% or more of the infrared light from visible light. In such material, copper oxide of a 5 nm to 50 nm (median value: 25 nm) particle diameter distribution is dispersed in silicon nitride as dispersant particles.

As an antireflection film 62, silicon oxynitride having a lower refractive index than the distributed refractive index lens 1b is formed on the topmost surface of the distributed refractive index lens.

The first feature of the lens having the present structure is that the structure on the light incidence surface-side is large and the structure on the substrate-side is small. With such a concave structure, the flatness of the lens surface increases and thus losses due to dispersion of incident light at the surface is reduced and light-collecting efficiency is improved. Furthermore, the second feature of the present lens is that the manufacturing process can be simplified and microfabrication can be made easy.

Furthermore, since the distributed refractive index lens 1b has a light-dispersion function, in order to prevent color-mixing due to oblique incident light passing through an adjacent distributed refractive index lens 1b, there is no unevenness among the surfaces of adjacent distributed refractive index lenses 1b, equal to or greater than 50% of the central wavelength of light transmitted by the light-collecting elements in the height direction of the solid-state image sensor 102. In other words, the unevenness among the surfaces of adjacent light-collecting elements are all less than 50% of the central wavelength of light transmitted by the light-collecting elements, in the height direction of the solid-state image sensor. In order to increase the flatness the lens surface, the thickness of each of the distributed refractive index lenses 1b must be made uniform. Since the desired light-diffusion properties are lost with simple thickening, the concentration of the particles to be dispersed is adjusted by lessening the particulate concentration when thickening the distributed refractive index lens 1b and, conversely, increasing the particulate concentration when making the distributed refractive index lens 1b thinner.

Next, FIG. 4 shows the reflective property. Although the surface of the distributed refractive index lens 1b is flat and smooth, in order to absorb incident light other than transmissive-light selected in each of the red color transmitting region 111, the green color transmitting region 112, and the blue color transmitting region 113, the reflectance in all the transmitting regions is a low value of 15% or less.

With the present embodiment, it is possible to implement a solid-state image sensor that has a high pixel count and includes a color filter having high color reproducibility.

### Manufacturing Method in the Third Embodiment

Next, a method for manufacturing the solid-state image sensor 102 in the present embodiment shall be described.

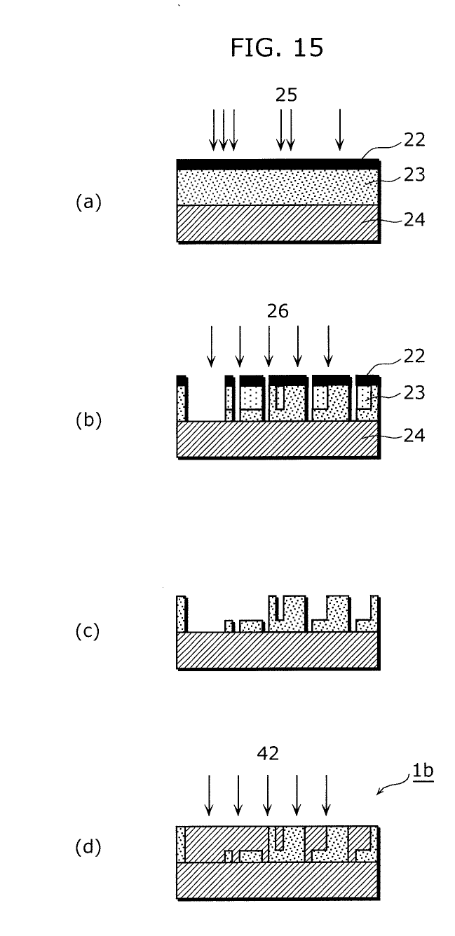

FIG. 15, (a) to (d), shows the manufacturing process for the distributed refractive index lens in the present embodiment.

First, the semiconductor integrated circuit 24, which includes light-receiving elements, wiring, a light-shielding layer, signal transmission units, and an antireflection layer, is formed on a silicon substrate using the normal semiconductor process. The size of one pixel is 2.25 square μm, and the light-receiving unit is 1.5 square μm. Subsequently, a silicon oxide film 23 is formed as a low refractive index material, using plasma CVD, and, after the resist 22 is applied thereon, patterning is performed through photolithography ((a) in FIG. 15, up to this point). The thickness of the silicon oxide film and the resist is 1.2 μm and 0.5 μm, respectively. In the same manner as in the process described in FIG. 8 in the previously described first embodiment, the patterning, BARC implanting, and etching 26 are performed repeatedly to form the two-staged concentric circle structure ((b) in FIG. 15). After leaving out the silicon oxide film 23 by removing the resist and the BARC ((c) in FIG. 15), the red color transmitting film 131, the green color transmitting film 132, and the blue color transmitting film 133 are implanted, as a high-refractive index material 42, in the same manner as in the manufacturing method exemplified in the first embodiment. Lastly, the distributed refractive index lens 1b implanted in the silicon oxide film 23 is formed by flattening the lens surface by the CMP method or etching so that there is no unevenness among the surfaces of adjacent distributed refractive index lenses 1b, equal to or greater than 50% of the central wavelength of light transmitted by the light-collecting elements, in the height direction of the solid-state image sensor 102. In other words, the distributed refractive index lens 1b in which the topmost layer of the light-collecting element is covered in a medium having a refractive index of 1.7 or higher is completed.

A film of silicon oxynitride is formed through the CVD method on the formed distributed refractive index lens 1b to form the antireflection film 62.

By adopting the process in FIG. 15, a lens of a high-refractive index material (silicon nitride, silicon oxide, and so on), for which microfabrication is generally considered to be difficult, can be formed using, as a template, silica series material and resin material for which microfabrication is comparatively easy. Furthermore, since the implanting of the top-stage and bottom-stage light-transmitting material can be performed collectively, it is possible to reduce the number of procedures and suppress production cost.

It should be noted that the silicon oxide implant ((c) in FIG. 15) may be formed using nanoimprinting.

It should be noted that although gold is exemplified as a particle for dispersing in the red color transmitting region 111, a material including copper, chromium or iron-chromium oxide may be used in place of or together with gold. Although cobalt-titanium-nickel-zinc oxide is exemplified as a particle for dispersing in the green color transmitting region 112, a material including cobalt-titanium oxide, nickel-titanium-zinc oxide or cobalt-zinc oxide may be used in place of or together with cobalt-titanium-nickel-zinc oxide. Although cobalt-aluminum oxide is exemplified as a particle for dispersing in the blue color transmitting region 113, a material including cobalt-chromium oxide may be used in place of or together with cobalt-aluminum oxide.

It should be noted that although a solid-state image sensor having three types of light-transmitting regions is exemplified in the third embodiment, it is also acceptable to form other types of light-transmitting regions in which particles made of at least two types among the following are mixed: gold, copper, chromium, iron-chromium oxide, cobalt-titanium-nickel-zinc oxide, cobalt-titanium oxide, nickel-titanium-zinc oxide, cobalt-zinc oxide, cobalt-aluminum oxide, and cobalt-chromium oxide.

It should be noted that although titanium oxide is exemplified as one material composing the distributed refractive index lenses 1b, silicon nitride or tantalum oxide, which are high-refractive index materials, is also acceptable.

It should be noted that although a material in which copper oxide particles are dispersed in silicon nitride is exemplified as a material composing the color separators 61b, silicon oxide, titanium oxide, or tantalum oxide may be used in place of silicon nitride, and particles of carbon, tin oxide or cobalt oxide may be dispersed in such medium in place of copper oxide.

As described above, according to the solid-state image sensor 102 in the present embodiment, since light-collection and light-dispersion are performed in the same element, the distance between the light-receiving element and the microlens is reduced and the aspect ratio is controlled thereby facilitating increasing pixel count, and, since incident light outside the regions to be transmitted through the lens is absorbed by the lens material, the reflection of light of a region outside the selected-transmissive-light off of the lens surface is suppressed and thus high color reproducibility is ensured. With this, a solid-state image sensor having a high pixel count and including color filters having high color reproducibility is realized.

Furthermore, since the distributed refractive index lenses in the present embodiment have a structure in which there is no unevenness among the surfaces of adjacent lenses, equal to or greater than 50% of the central wavelength of light transmitted by the light-collecting elements, in the height direction of the solid-state image sensor 102, color-mixing of oblique incident light transmitted by an adjacent filter is prevented.

### Fourth Embodiment

Next, a solid-state image sensor in a fourth embodiment shall be described.

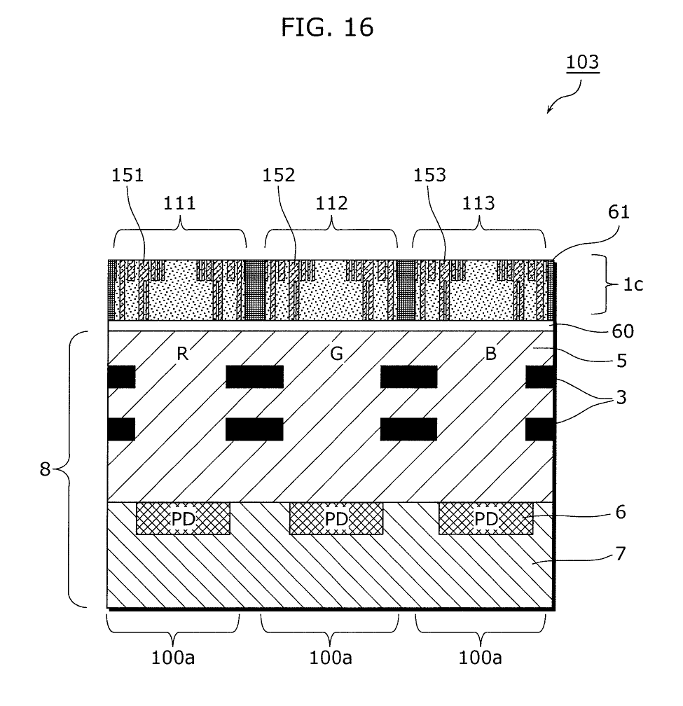

FIG. 16 is a diagram showing the basic structure of a solid-state image sensor 103 in the present embodiment. The solid-state image sensor 103 is an assembly of the two-dimensionally arranged pixels 100a, and includes distributed refractive index lenses 1c, the color separators 61, the antireflection film 60, the electrical wiring 3, the inter-layer insulating film 5, the light-receiving elements 6, and the Si substrate 7. Each of the light-receiving elements 6 receives light collected by a corresponding one of the refractive index lenses 1 and generates an electric signal. The electrical wiring 3 transfer the electric signals from the light-receiving elements 6.

The solid-state image sensor 103 in the present embodiment has basically the same structure as that in the first embodiment, but is different from the first embodiment in the material (medium of the high-refractive index material, and the low-refractive index material) of the distributed refractive index lenses 1c. Hereinafter, constituent elements that are the same as those in the first embodiment are given the same reference numerals, and description shall be centered on the points of difference from the first embodiment.

As shown in FIG. 16, the distributed refractive index lenses 1c are provided with the functions of both a microlens (that is, a light-collecting function) and a color filter (that is, a light-dispersion function), and are configured of light-collecting elements (the red color transmitting region 111, the green color transmitting region 112, and the blue color transmitting region 113) corresponding to the regions of light that are transmitted. The distributed refractive index lenses 1c are covered (filled) with a red color transmitting material 151 of a low refractive index, a green color transmitting material 152 of a low refractive index, and a blue color transmitting material 153 of a low refractive index, as the low-refractive index material, unlike in the first embodiment which uses air in its formation.

In order to implement the light-dispersion function corresponding to the aforementioned three colors, particles which include metal and are equal to or less than 100 nm in particle diameter are dispersed in each of the distributed refractive index lenses 1c. In the present embodiment, gold of a 5 nm to 50 nm (median value: 15 nm) particle diameter distribution, cobalt-titanium-nickel-zinc oxide of a 5 nm to 50 nm (median value: 25 nm) particle diameter distribution, and cobalt-aluminum oxide of a 5 nm to 50 nm (median value: 20 nm) particle diameter distribution are dispersed in titanium oxide as dispersant particles for the red color transmitting region 111, the green color transmitting region 112, and the blue color transmitting region 113, respectively, in the portion of the high-refractive index material. It should be noted that titanium oxide (refractive index n=2.5) is an example of a medium which transmits 50% or more of infrared light from the visible light that is light-received by the solid-state image sensor 103 with a refractive index of 1.7 or greater. Specifically, titanium oxide is an example of a transparent inorganic medium that can provide a light-collecting function.

Furthermore, gold of a 5 nm to 50 nm (median value: 15 nm) particle diameter distribution, cobalt-titanium-nickel-zinc oxide of a 5 nm to 50 nm (median value: 25 nm) particle diameter distribution, and cobalt-aluminum oxide of a 5 nm to 50 nm (median value: 20 nm) particle diameter distribution are dispersed in silicon oxide as dispersant particles for the red color transmitting material 151 of a low refractive index, the green color transmitting material 152 of a low refractive index, and the blue color transmitting material 153 of a low refractive index, respectively, in the portion of the low-refractive index material of the distributed refractive index lenses 1c.

In this manner, in the distributed refractive index lenses 1c in the present embodiment, although the high-refractive index material and the low-refractive index material are made of different media, the particles dispersed in both media are the same.

Each of the distributed refractive index lenses 1c is electrically insulated from the corresponding electrical wiring 3 by the inter-layer insulating film 5 and the antireflection film 60 in which silicon nitride films are stacked above and below a silicon oxynitride film.

The color separators 61, provided between adjacent light-collecting elements (the red color transmitting region 111, the green color transmitting region 112, and the blue color transmitting region 113), prevent light from leaking between the adjacent light-collecting elements and are made of a material which absorbs 50% or more of the infrared light from visible light. In such material, copper oxide of a 5 nm to 50 nm (median value: 25 nm) particle diameter distribution is dispersed in silicon oxide as dispersant particles.

With the present embodiment, it is possible to implement a solid-state image sensor that has a high pixel count and includes a color filter having high color reproducibility.

### Manufacturing Method in the Fourth Embodiment

Next, a method for manufacturing the solid-state image sensor in the present embodiment shall be described.

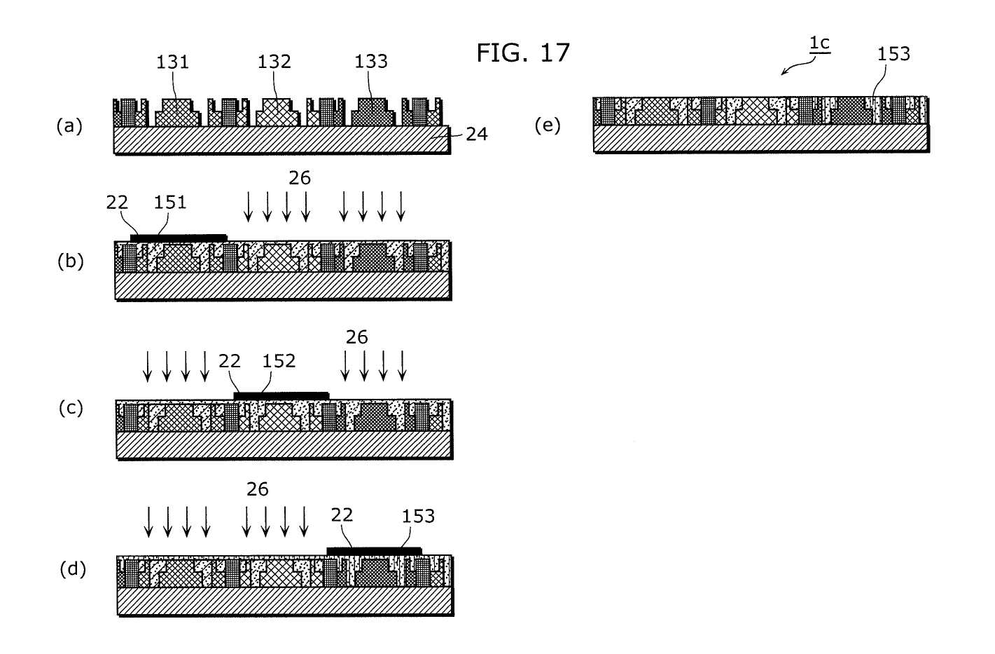

FIG. 17, (a) to (e), shows the manufacturing process. First, as in the manufacturing method in the first or second embodiments, the color separators 61 and the high-refractive index material portion (the red color transmitting film 131, the green color transmitting film 132, and the blue color transmitting film 133) of the distributed refractive index lenses 1c are formed on a semiconductor integrated circuit ((a) in FIG. 17, up to this point).

Next, in order to form the low-refractive index portion of the distributed refractive index lenses 1c, first, a gold particle solution dispersed in a SOG solution is applied by spin-on and provisionally fired at 250 degrees Celsius to form the red color transmitting material 151. After applying a resist, patterning of the resist is performed using again light exposure ((b) in FIG. 17). The red color transmitting material 151 of a low refractive index is formed through dry etching and wet etching, the resist is removed, and the red color transmitting material 151 is fired at 400 degrees Celsius. Next, a cobalt-titanium-nickel-zinc oxide particle solution dispersed in a SOG solution is applied by spin-on and provisionally fired at 250 degrees Celsius to form the green color transmitting material 152, and after a resist is applied, patterning of the resist is performed using light exposure again ((c) in FIG. 17). The green color transmitting material 152 of a low refractive index is formed through dry etching and wet etching. Here, since the dry etching rate and the wet etching rate of the low-refractive index red color transmitting material 151 which is fired at 400 degrees Celsius is low compared to the low-refractive index green color transmitting material 152 which is not sufficiently crystallized by being fired at only 250 degrees Celsius, the low-refractive index red color transmitting material 151 is substantially unetched. Subsequently, the resist is removed and the low-refractive index green color transmitting material 152 is fired at 400 degrees Celsius. Next, a cobalt-aluminum oxide particle solution dispersed in a SOG solution is applied by spin-on and provisionally fired at 250 degrees Celsius to form the blue color transmitting material 153, and after a resist is applied, patterning of the resist is performed using light exposure again ((d) in FIG. 17). Here, since the dry etching rate and the wet etching rate of the low-refractive index red color transmitting material 151 and the low-refractive index green color transmitting material 152 which are fired at 400 degrees Celsius is low compared to the low-refractive index blue color transmitting material 153 which is not sufficiently crystallized by being fired at only 250 degrees Celsius, the low-refractive index red color transmitting material 151 and the low-refractive index green color transmitting material 152 are substantially unetched. Subsequently, the resist is removed and the low-refractive index blue color transmitting material 153 is fired at 400 degrees Celsius ((e) in FIG. 17).

It should be noted that although gold is exemplified as a particle for dispersing in the red color transmitting region 111, a material including copper, chromium or iron-chromium oxide may be used in place of or together with gold. Although cobalt-titanium-nickel-zinc oxide is exemplified as a particle for dispersing in the green color transmitting region 112, a material including cobalt-titanium oxide, nickel-titanium-zinc oxide or cobalt-zinc oxide may be used in place of or together with cobalt-titanium-nickel-zinc oxide. Although cobalt-aluminum oxide is exemplified as a particle for dispersing in the blue color transmitting region 113, a material including cobalt-chromium oxide may be used in place of or together with cobalt-aluminum oxide.

It should be noted that although a solid-state image sensor having three types of light-transmitting regions is exemplified in the fourth embodiment, it is also acceptable to form other types of light-transmitting regions in which particles made of at least two types among the following are mixed: gold, copper, chromium, iron-chromium oxide, cobalt-titanium-nickel-zinc oxide, cobalt-titanium oxide, nickel-titanium-zinc oxide, cobalt-zinc oxide, cobalt-aluminum oxide, and cobalt-chromium oxide.

It should be noted that although titanium oxide is exemplified as one material composing the high-refractive index portion of the distributed refractive index lenses 1c, silicon nitride or tantalum oxide, which are high-refractive index materials, is also acceptable.

It should be noted that although silicon oxide is exemplified as a material composing the low-refractive index red color transmitting material 151, the low-refractive index green color transmitting material 152, and the low-refractive index blue color transmitting material 153, a transparent resin is also acceptable.

It should be noted that although a material in which copper oxide particles are dispersed in silicon oxide is exemplified as a material composing the color separators 61, silicon nitride, titanium oxide, or tantalum oxide may be used in place of silicon oxide, and particles of tin oxide or cobalt oxide may be dispersed in such medium in place of copper oxide.

As described above, according to the solid-state image sensor 103 in the present embodiment, since light-collection and light-dispersion are performed in the same element, the distance between the light-receiving element and the microlens is reduced and the aspect ratio is controlled thereby facilitating increasing pixel count, and, since incident light outside the regions to be transmitted through the lens is absorbed by the lens material, the reflection of light of a region outside the selected-transmissive-light off of the lens surface is suppressed and thus high color reproducibility is ensured. With this, a solid-state image sensor having a high pixel count and including color filters having high color reproducibility is realized.

Furthermore, in the distributed refractive index lenses in the present embodiment, the particles included in the medium (of the high-refractive index material) and the particles included in the light-transmitting films (low-refractive index material) include the same metal, light-dispersion of the same property on all the regions of the lenses is realized.

### Fifth Embodiment

Next, a solid-state image sensor in a fifth embodiment shall be described.

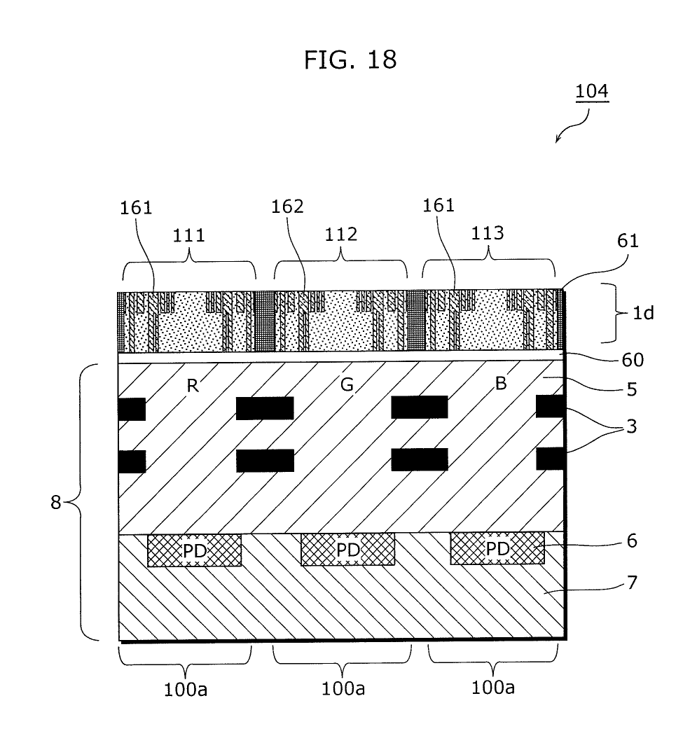

FIG. 18 is a diagram showing the basic structure of a solid-state image sensor 104 in the present embodiment. The solid-state image sensor 104 is an assembly of the two-dimensionally arranged pixels 100a, and includes distributed refractive index lenses Id, the color separators 61, the antireflection film 60, the electrical wiring 3, the inter-layer insulating film 5, the light-receiving elements 6, and the Si substrate 7. Each of the light-receiving elements 6 receives light collected by a corresponding one of the refractive index lenses 1 and generates an electric signal. The electrical wiring 3 transfer the electric signals from the light-receiving elements 6.

The solid-state image sensor 104 in the present embodiment has basically the same structure as that in the first embodiment, but is different from the first embodiment in the material (medium of the high-refractive rate material, and the low-refractive rate material) of the distributed refractive index lenses 1d. Hereinafter, constituent elements that are the same as those in the first embodiment are given the same reference numerals, and description shall be centered on the points of difference from the first embodiment.

As shown in FIG. 18, the distributed refractive index lenses 1d are provided with the functions of both a microlens (that is, a light-collecting function) and a color filter (that is, a light-dispersion function), and are configured of light-collecting elements (the red color transmitting region 111, the green color transmitting region 112, and the blue color transmitting region 113) corresponding to the regions of light that are transmitted. The distributed refractive index lenses 1d are covered (filled) with a transparent low-refractive index material 161, as the low-refractive index material, unlike in the first embodiment which uses air in its formation.

In order to implement the light-dispersion function corresponding to the aforementioned three colors, particles which include metal and are equal to or less than 100 nm in particle diameter are dispersed in each of the distributed refractive index lenses 1d. In the present embodiment, gold of a 5 nm to 50 nm (median value: 15 nm) particle diameter distribution, cobalt-titanium-nickel-zinc oxide of a 5 nm to 50 nm (median value: 25 nm) particle diameter distribution, and cobalt-aluminum oxide of a 5 nm to 50 nm (median value: 20 nm) particle diameter distribution are dispersed in titanium oxide as dispersant particles for the red color transmitting region 111, the green color transmitting region 112, and the blue color transmitting region 113, respectively, in the portion of the high-refractive index material. It should be noted that titanium oxide (refractive index n=2.5) is an example of a medium which transmits 50% or more of infrared light from the visible light that is light-received by the solid-state image sensor 104 with a refractive index of 1.7 or greater. Specifically, titanium oxide is an example of a transparent inorganic medium that can provide a light-collecting function.

Furthermore, the transparent low-refractive index material 161 which is the low-refractive index material portion of the distributed refractive index lenses 1d is SOG.

In this manner, in the distributed refractive index lenses 1d in the present embodiment, the high-refractive index material and the low-refractive index material are made of different media, and the particles dispersed in both media are different.

Each of the distributed refractive index lenses 1d is electrically insulated from the corresponding electrical wiring 3 by the inter-layer insulating film 5 and the antireflection film 60 in which silicon nitride films are stacked above and below a silicon oxynitride film.

With the present embodiment, it is possible to implement a solid-state image sensor that has a high pixel count and includes a color filter having high color reproducibility.

### Manufacturing Method in the Fifth Embodiment

Next, a method for manufacturing the solid-state image sensor in the present embodiment shall be described.

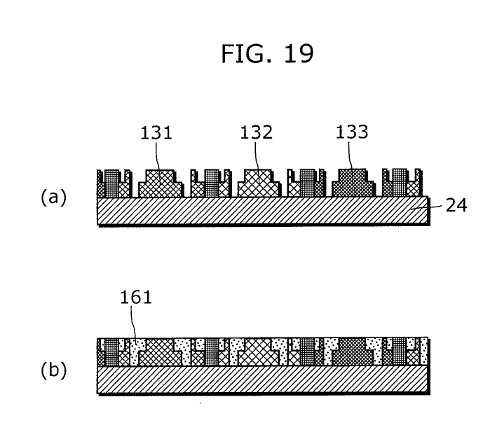

FIG. 19, (a) to (e), shows the manufacturing process. First, as in the manufacturing method in the first or second embodiments, the color separators 61 and the high-refractive index material portion (the red color transmitting film 131, the green color transmitting film 132, and the blue color transmitting film 133) of the distributed refractive index lenses 1d are formed on a semiconductor integrated circuit ((a) in FIG. 19, up to this point).

Next, in order to form the low-refractive index portion of the distributed refractive index lenses 1d, first, a silicon oxide particle solution dispersed in a transparent resin is applied by spin-on and provisionally fired at 250 degrees Celsius to form the transparent low-refractive index material 161 ((b) in FIG. 19).

It should be noted that although gold is exemplified as a particle for dispersing in the red color transmitting region 111, a material including copper, chromium or iron-chromium oxide may be used in place of or together with gold. Although cobalt-titanium-nickel-zinc oxide is exemplified as a particle for dispersing in the green color transmitting region 112, a material including cobalt-titanium oxide, nickel-titanium-zinc oxide or cobalt-zinc oxide may be used in place of or together with cobalt-titanium-nickel-zinc oxide. Although cobalt-aluminum oxide is exemplified as a particle for dispersing in the blue color transmitting region 113, a material including cobalt-chromium oxide may be used in place of or together with cobalt-aluminum oxide.

It should be noted that although a solid-state image sensor having three types of light-transmitting regions is exemplified in the fifth embodiment, it is also acceptable to form other types of light-transmitting regions in which particles made of at least two types among the following are mixed: gold, copper, chromium, iron-chromium oxide, cobalt-titanium-nickel-zinc oxide, cobalt-titanium oxide, nickel-titanium-zinc oxide, cobalt-zinc oxide, cobalt-aluminum oxide, and cobalt-chromium oxide.

It should be noted that the transparent low-refractive index material 161 may be of a material in which silicon oxide of a 5 nm to 50 nm (median value: 30 nm) particle diameter distribution is dispersed, as dispersant particles, in a transparent resin such as acrylic or polycarbonate or polystyrene.

It should be noted that although titanium oxide is exemplified as one material composing the distributed refractive index lenses 1d, silicon nitride or tantalum oxide, which are high-refractive index materials, is also acceptable.

It should be noted that although a material in which copper oxide particles are dispersed in silicon oxide is exemplified as a material composing the color separators 61, silicon nitride, titanium oxide, or tantalum oxide may be used in place of silicon oxide, and particles of tin oxide or cobalt oxide may be dispersed in such medium in place of copper oxide.

As described above, according to the solid-state image sensor 104 in the present embodiment, since light-collection and light-dispersion are performed in the same element, the distance between the light-receiving element and the microlens is reduced and the aspect ratio is controlled thereby facilitating increasing pixel count, and, since incident light outside the regions to be transmitted through the lens is absorbed by the lens material, the reflection of light of a region outside the selected-transmissive-light off of the lens surface is suppressed and thus high color reproducibility is ensured. With this, a solid-state image sensor having a high pixel count and including color filters having high color reproducibility is realized.

Furthermore, in the distributed refractive index lenses in the present embodiment, the particles included in the medium (of the high-refractive index material) and the particles included in the light-transmitting films (low-refractive index material) are different, the level of design freedom in realizing the light-diffusion properties increases and thus light-diffusion having the desired property can be realized.

### Sixth Embodiment

Next, a solid-state image sensor in a sixth embodiment shall be described.

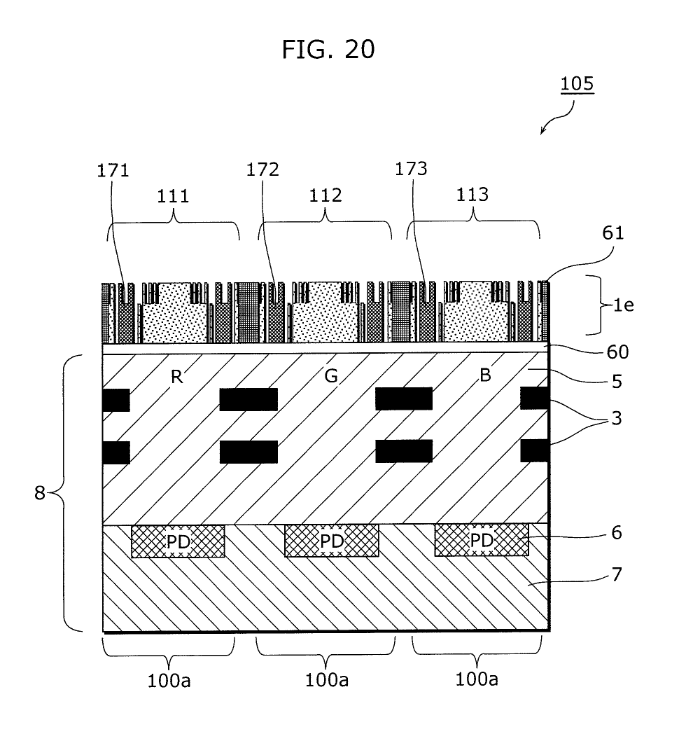

FIG. 20 is a diagram showing the basic structure of a solid-state image sensor 105 in the present embodiment. The solid-state image sensor 105 is an assembly of the two-dimensionally arranged pixels 100a, and includes distributed refractive index lenses 1e, the color separators 61, the antireflection film 60, the electrical wiring 3, the inter-layer insulating film 5, the light-receiving elements 6, and the Si substrate 7. Each of the light-receiving elements 6 receives light collected by a corresponding one of the refractive index lenses 1 and generates an electric signal. The electrical wiring 3 transfer the electric signals from the light-receiving elements 6.

The solid-state image sensor 105 in the present embodiment has basically the same structure as that in the first embodiment, but is different from the first embodiment in the formation of low-transmissivity regions 171 to 173 in the respective transmission regions 111 to 113 of the distributed refractive index lenses 1e. Hereinafter, constituent elements that are the same as those in the first embodiment are given the same reference numerals, and description shall be centered on the points of difference from the first embodiment.

As shown in FIG. 20, the distributed refractive index lenses 1e are provided with the functions of both a microlens (that is, a light-collecting function) and a color filter (that is, a light-dispersion function), are configured of light-collecting elements (the red color transmitting region 111, the green color transmitting region 112, and the blue color transmitting region 113) corresponding to the regions of light that are transmitted, and have the low-transmissivity regions 171, 172, and 173 in the peripheral portions.

In order to implement the light-dispersion function corresponding to the aforementioned three colors, particles which include metal and are equal to or less than 100 nm in particle diameter are dispersed in each of the distributed refractive index lenses 1e. In the present embodiment, gold of a 5 nm to 50 nm (median value: 15 nm) particle diameter distribution, cobalt-titanium-nickel-zinc oxide of a 5 nm to 50 nm (median value: 25 nm) particle diameter distribution, and cobalt-aluminum oxide of a 5 nm to 50 nm (median value: 20 nm) particle diameter distribution are dispersed in silicon oxide as dispersant particles for the red color transmitting region 111, the green color transmitting region 112, and the blue color transmitting region 113, respectively. It should be noted that silicon oxide (refractive index n=1.45) is an example of a medium which transmits 50% or more of infrared light from the visible light that is light-received by the solid-state image sensor 105 with a refractive index of 1.4 or greater. Specifically, silicon oxide is an example of a transparent inorganic medium that can provide a light-collecting function.

In the distributed refractive index lenses 1e configured of the red color transmitting region 111, the green color transmitting region 112, and the blue color transmitting region 113, only the transmissivity is reduced while the light-dispersion profile is kept the same by increasing the concentration of metallic particles to about 5 times for regions having low transmissivity among the respective low-transmissivity regions 171, 172, and 173 and the rest of the regions. With this, distributed refractive index lenses 1e in the present invention have a concentric distribution of wavelength dependence of the absorption property.

As described above, according to the solid-state image sensor 105 in the present embodiment, since light-collection and light-dispersion are performed in the same element, the distance between the light-receiving element and the microlens is reduced and the aspect ratio is controlled thereby facilitating increasing pixel count, and, since incident light outside the regions to be transmitted through the lens is absorbed by the lens material, the reflection of light of a region outside the selected-transmissive-light off of the lens surface is suppressed and thus high color reproducibility is ensured. With this, a solid-state image sensor having a high pixel count and including color filters having high color reproducibility is realized.

Furthermore, in the distributed refractive index lenses in the present embodiment, low-transmissivity regions are formed in the peripheral portions of the transmission regions for each color, and it becomes easy to optimize transmissivity between the central portion and the peripheral portion of the lenses so as to have a concentric distribution of wavelength dependence of the absorption property, and as a result, a solid-state image sensor having a high light-collecting efficiency is realized.

### Seventh Embodiment

Next, a solid-state image sensor in a seventh embodiment shall be described.

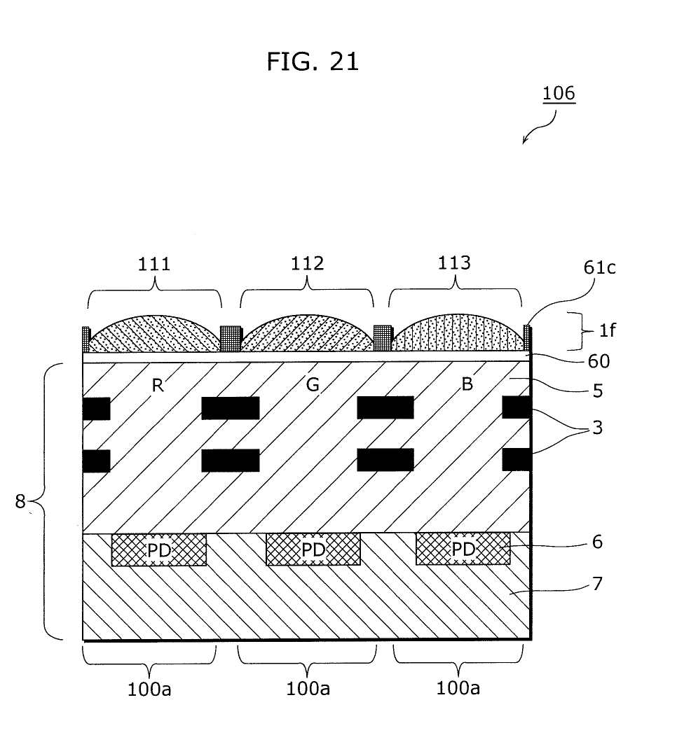

FIG. 21 is a diagram showing a solid-state image sensor 106 including distributed refractive index lenses 1f having a convex structure in the seventh embodiment. The solid-state image sensor 106 is an assembly of the two-dimensionally arranged pixels 100a, and includes distributed refractive index lenses if, color separators 61c, the antireflection film 60, the electrical wiring 3, the inter-layer insulating film 5, the light-receiving elements 6, and the Si substrate 7. Each of the light-receiving elements 6 receives light collected by a corresponding one of the refractive index lenses 1 and generates an electric signal. The electrical wiring 3 transfer the electric signals from the light-receiving elements 6.

The solid-state image sensor 106 in the present embodiment has basically the same structure as that in the first embodiment, but is different from the first embodiment in the material and structure of the distributed refractive index lenses 1f, and the material of the color separators 61c. Hereinafter, constituent elements that are the same as those in the first embodiment are given the same reference numerals, and description shall be centered on the points of difference from the first embodiment.

The distributed refractive index lenses 1f are provided with the functions of both a microlens (that is, a light-collecting function) and a color filter (that is, a light-dispersion function), are configured of light-collecting elements (the red color transmitting region 111, the green color transmitting region 112, and the blue color transmitting region 113) corresponding to the regions of light that are transmitted, and are characterized in having a top surface which is a convex curve. The feature of this structure is that the lithography and etching for forming the shape of the distributed refractive index lenses 1f are unnecessary and thus the manufacturing process can be simplified.

The particles to be dispersed in the red color transmitting region 111 is of a material including at least gold, copper, chromium, or iron-chromium oxide; the particles to be dispersed in the green color transmitting region 112 is of a material including at least cobalt-titanium-nickel-zinc oxide, cobalt-titanium oxide, nickel-titanium-zinc oxide, or cobalt-zinc oxide; the particles to be dispersed in the blue color transmitting region 113 is of a material including at least cobalt-aluminum oxide, or cobalt-chromium oxide.

It should be noted that in the solid-state image sensor 106 in the present embodiment, aside from the three types of light-transmitting regions, it is also acceptable to form other types of light-transmitting regions in which particles made of at least two types among the following are mixed: gold, copper, chromium, iron-chromium oxide, cobalt-titanium-nickel-zinc oxide, cobalt-titanium oxide, nickel-titanium-zinc oxide, cobalt-zinc oxide, cobalt-aluminum oxide, and cobalt-chromium oxide.

The material composing the distributed refractive index lenses 1f is a material including at least silicon oxide, silicon nitride, titanium oxide, or tantalum oxide.

The material composing the color separators 61c is a material which includes, as a medium, at least silicon oxide, silicon nitride, titanium oxide, or tantalum oxide; and includes, as particles to be dispersed, at least particles of copper oxide, carbon, tin oxide, or cobalt oxide.

With the present embodiment, it is possible to implement a solid-state image sensor that has a high pixel count and includes a color filter having high color reproducibility.

### Manufacturing Method in the Seventh Embodiment

Next, a method for manufacturing the solid-state image sensor in the present embodiment shall be described.

The manufacturing process up to the formation of the red transmissive film 131, the green transmissive film 132, and the blue transmissive film 133 is performed in the same manner as in the manufacturing method exemplified in the first embodiment.

Forming into the convex lens shape is performed by adding a 450 degree Celsius-thermal processing after forming the red transmissive film 131, the green transmissive film 132, and the blue transmissive film 133. At this time, the process may be performed under ultraviolet ray irradiation.

It should be noted that nanoimprinting may be used in the forming of the convex lens shape.

As described above, according to the solid-state image sensor 106 in the present embodiment, since light-collection and light-dispersion are performed in the same element, the distance between the light-receiving element and the microlens is reduced and the aspect ratio is controlled thereby facilitating increasing pixel count, and, since incident light outside the regions to be transmitted through the lens is absorbed by the lens material, the reflection of light of a region outside the selected-transmissive-light off of the lens surface is suppressed and thus high color reproducibility is ensured. With this, a solid-state image sensor having a high pixel count and including color filters having high color reproducibility is realized.

Furthermore, with the distributed refractive index lenses in the present embodiment, the lithography and etching for forming the shape of the lenses become unnecessary, and thus the manufacturing process is simplified.

Although the solid-state image sensor in the present invention has been described thus far based on the first through seventh embodiments, the present invention is not limited to these embodiments. Other embodiments that are realized by combining arbitrary constituent elements in the first to seventh embodiments, modifications obtained by executing various variations on the first to seventh embodiments without departing from the fundamentals of the present invention, and various devices in which the solid-state image sensor in the present invention is built-in are included in the present invention.

### INDUSTRIAL APPLICABILITY

The solid-state image sensor in the present invention is useful as a solid-state image sensor used in digital cameras such as digital still cameras and video cameras, and particularly as a solid-state image sensor having minute pixels necessary for realizing a high pixel count or a small chip area.

What is claimed is:

1. A solid-state image sensor comprising:
light-collecting elements each of which is a medium containing dispersant particles;
light-receiving elements each of which is provided for a corresponding one of said light-collecting elements, and which receives light collected by the corresponding one of said light-collecting elements and generates an electric signal; and
electrical wiring for transferring the electric signal,
wherein each of said light-collecting elements has one of plural light-dispersion functions that are different depending on said corresponding light-receiving elements.

2. The solid-state image sensor according to claim 1,
wherein the medium transmits 50% or more of infrared light included in visible light received by said solid-state image sensor having a refractive index of 1.4 or greater, and contains the dispersant particles that are between 5 nm and 50 nm in diameter.

3. The solid-state image sensor according to claim 2,
wherein said light-collecting elements include a first-type light-collecting element, a second-type light-collecting element, and a third-type light-collecting element, said first-type light collecting element containing at least gold, copper, chromium, or iron-chromium oxide as the dispersant particles, said second-type light-collecting element containing at least cobalt-titanium-nickel-zinc oxide, cobalt-titanium oxide, nickel-titanium-zinc oxide, or cobalt-zinc oxide as the dispersant particles, and said third-type light-collecting element containing at least cobalt-aluminum oxide, or cobalt-chromium oxide as the dispersant particles.

4. The solid-state image sensor according to claim 2,
wherein each of said light-collecting elements contains the dispersant particles composed of at least one type of organic molecules.

5. The solid-state image sensor according to claim 1,
wherein each of said light-collecting elements has a convex shape.

6. The solid-state image sensor according to claim 1,
wherein each of said light-collecting elements has an effective refractive index distribution of a light-transmitting film having concentric structural elements each having a line-width that is comparable to or shorter than a wavelength of incident light to be collected.

7. The solid-state image sensor according to claim 6,
wherein each of said light-collecting elements is covered by a light-transmitting film having a refractive index different from a refractive index of the medium, and which transmits 50% or more of infrared light included in visible light.

8. The solid-state image sensor according to claim 7,
wherein said light-transmitting film contains dispersant particles including a metal.

9. The solid-state image sensor according to claim 8,
wherein the dispersant particles contained in the medium and the dispersant particles contained in said light-transmitting film include a same metal.

10. The solid-state image sensor according to claim 6,
wherein each of said light-collecting elements has a concentric distribution of wavelength dependence of an absorption property.

11. The solid-state image sensor according to claim 1,
wherein the medium contains silicon and oxygen.

12. The solid-state image sensor according to claim 6, wherein the medium transmits 50% or more of infrared light included in visible light received by said solid-state image sensor which has a refractive index of 1.7 or greater, and a topmost layer of said light-collecting element is covered by the medium.

13. The solid-state image sensor according to claim 6,
wherein each of said light-collecting elements has a refractive index distribution that is different depending on said corresponding light-receiving elements.

14. The solid-state image sensor according to claim 12,
wherein unevenness among surfaces of adjacent ones of said light-collecting elements is less than 50% of a central wavelength of light in a height direction of said solid-state image sensor, the light being transmitted by said light-collecting elements.

15. The solid-state image sensor according to claim 12,
wherein an upper portion of each of said light-collecting elements is covered by a material having a lower refractive index than the medium.

16. The solid-state image sensor according to claim 1,
wherein said light-collecting elements are separated by a material which is provided between adjacent ones of said light receiving elements and absorbs 50% or more of infrared light included in visible light.

17. The solid-state image sensor according to claim 1,
wherein each of said light receiving elements has a reflectance from visible light to infrared light of 15% or less.

18. The solid-state image sensor according to claim 1,
wherein said light-collecting elements are insulated from said light-receiving elements and said electrical wiring.

19. The solid-state image sensor according to claim 2,
wherein both the medium and the dispersant particles are composed of inorganic material.

20. A method for manufacturing a solid-state image sensor, said method comprising:
forming, on a substrate, a semiconductor circuit including light-receiving elements, electrical wiring, a light-shielding layer, signal transmission units, and an antireflection film;
forming color separators on the formed semiconductor circuit;
forming each of a red color transmitting film, a green color transmitting film, and a blue color transmitting film on corresponding regions enclosed by the formed color separators; and
etching or patterning, into a concentric circle shape, the each of the red color transmitting film, the green color transmitting film, and the blue color transmitting film that have been formed.
